(19) United States
(12) Patent Application Publication
(10) Pub. No.: US 2023/0420504 A1
(43) Pub. Date: Dec. 28, 2023

(54) HIGH-VOLTAGE SEMICONDUCTOR DEVICES AND METHODS OF FORMATION

(71) Applicant: Taiwan Semiconductor Manufacturing Company, Ltd., Hsinchu (TW)

(72) Inventors: Wan-Jyun SYUE, Hsinchu County (TW); Hsueh-Liang CHOU, Jhubei City (TW); Yi-Jen LO, Hsinchu City (TW)

(21) Appl. No.: 17/809,099

(22) Filed: Jun. 27, 2022

(51) Int. Cl. H01L 29/06; H01L 29/786; H01L 29/775; H01L 29/66; H01L 29/78; H01L 21/8234

(52) U.S. Cl. CPC H01L 29/0673; H01L 29/78696; H01L 29/78618; H01L 29/775; H01L 29/66439; H01L 29/0649; H01L 29/7851; H01L 29/66795; H01L 21/823431; H01L 21/823412; H01L 21/823418; H01L 21/823481

(57) ABSTRACT

A high-voltage transistor may include a planar active region for a first source/drain active region, a second source/drain active region, and/or a channel active region. The planar active region(s) are included instead of a plurality of fin active regions to reduce the amount of surface area of the active regions in the high-voltage transistor that is in contact with surrounding dielectric layers of the high-voltage transistor. In other words, the planar active region(s) reduce the interface surface area between the silicon-based active regions of the high-voltage transistor and the surrounding oxide-based dielectric layers. The reduced interface surface area may reduce the occurrence of charge trapping in the high-voltage transistor, which may result in increased performance stability for the high-voltage transistor and/or may provide increased operational lifetime of the high-voltage transistor.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). As another example, in a nanostructure transistor, the gate structure wraps around a plurality of channel regions in a fin structure such that the gate structure surrounds each of the plurality of channel regions. Source region and drain region (e.g., epitaxial regions) are located on opposing sides of the gate structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of an example semiconductor device described herein.

FIGS. 3A-3C are diagrams of an example semiconductor device described herein.

FIGS. 4A-4C are diagrams of an example semiconductor device described herein.

FIGS. 5A-5C are diagrams of an example semiconductor device described herein.

FIGS. 6A-6C are diagrams of an example semiconductor device described herein.

FIGS. 7A-7C are diagrams of an example semiconductor device described herein.

FIGS. 8A-8C are diagrams of an example semiconductor device described herein.

FIGS. 9A-9C are diagrams of an example semiconductor device described herein.

FIGS. 10A-10F, 11A-11C, 12A-12D, 13A, and 13B are diagrams of example implementations described herein.

FIG. 14 is a diagram of example components of one or more devices of FIG. 1 described herein.

FIG. 15 is a flowchart of an example processes associated with forming a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a fin-based transistor (e.g., a fin field effect transistor (finFET), a nanostructure transistor) may be configured to operate at a higher drain voltage relative to a low-voltage fin-based transistor. Low-voltage fin-based transistors may be used in applications such as logic circuits (e.g., processors), memory (e.g., static random access memory (SRAM), and/or input/output (I/O) circuits, among other examples. High-voltage fin-based transistors may be used in applications such as integrated circuit (IC) drivers, power ICs, image sensors, power management, display driver ICs (DDICs), bipolar complementary metal oxide semiconductor (CMOS) diffused metal oxide semiconductor (DMOS) ICs (BCD ICs), and/or image signal processing (ISP) ICs, among other examples.

A single high-voltage fin-based transistor may include a plurality of fin structures that provide a plurality of channel regions under a single gate structure. Including more than one fin structure enables the high-voltage fin-based transistor to operate at higher voltages and/or increases the drive current capability of the high-voltage fin-based transistor while still achieving good control over the channel regions. However, charge trapping can occur at the interfaces between dielectric regions (e.g., shallow trench isolation (STI) regions, gate oxide layers, interlayer dielectric (ILD) layers) of the high-voltage fin-based transistor and the fin structures of the high-voltage fin-based transistor. In particular, electrons and/or holes may become trapped at the interfaces during operation and/or stress of the high-voltage fin-based transistor.

The use of a plurality of fin structures in the high-voltage fin-based transistor increases the surface area of the fin structures that is in contact with surrounding dielectric layers. In other words, the high-voltage fin-based transistor may have a greater interface surface area between silicon-based fin structures and surrounding oxide-based dielectric layers relative to a low-voltage fin-based transistor. The increased interface surface area may increase the occurrence of charge trapping in the high-voltage fin-based transistor, which may result in unstable performance for the high-voltage fin-based transistor and/or may result in reduced lifetime of the high-voltage fin-based transistor. For example, the increased occurrence of charge trapping in the high-voltage fin-based transistor may result in reduced operation stability, reduced reliability, reduced time-dependent dielectric breakdown (TDDB) times for the dielectric layers of the high-voltage fin-based transistor, increased drain-source on resistance (R_{dson}), breakdown voltage, and/or reduced hot-carrier injection (HCl), among other examples.

Some implementations described herein provide high-voltage transistors that include one or more planarized active regions. As described herein, a high-voltage transistor may include a planar active region for a first source/drain active region, a second source/drain active region, and/or a channel active region. For example, the first source/drain active region is a planar source active region, and/or the second source/drain active region is a drain active region. The planar active region(s) are included instead of a plurality of fin active regions to reduce the amount of surface area of the active regions in the high-voltage transistor that is in contact with surrounding dielectric layers of the high-voltage transistor. In other words, the planar active region(s) reduce the interface surface area between the silicon-based active regions of the high-voltage transistor and the surrounding oxide-based dielectric layers. The reduced interface surface area may reduce the occurrence of charge trapping in the high-voltage transistor, which may result in increased performance stability for the high-voltage transistor and/or may provide increased operational lifetime of the high-voltage transistor. For example, the reduced occurrence of charge trapping in the high-voltage transistor provided by the planar active region(s) may result in increased operation stability, increased reliability, increased time-TDDB times for the dielectric layers of the high-voltage transistor, reduced R_{dson}, increased breakdown voltage, and/or increased HCl performance, among other examples.

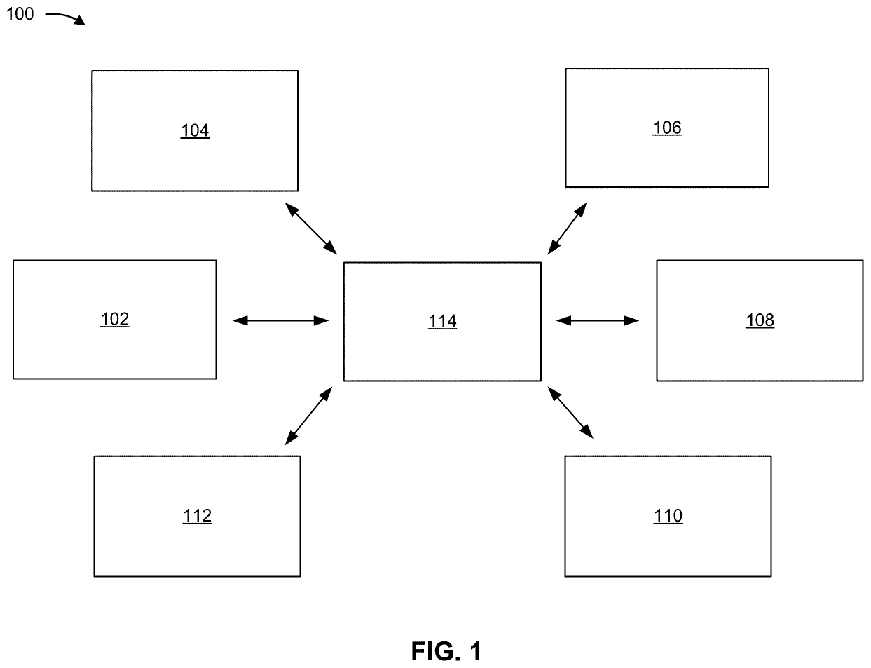

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-112 and/or the wafer/die transport tool 114 may perform one or more semiconductor processing operations described herein. For example, one or more of the semiconductor processing tools 102-112 and/or the wafer/die transport tool 114 may form a first source/drain region including a source active region that extends above a substrate of a semiconductor device; may form a second source/drain region including a drain active region that extends above the substrate, where at least one of the source active region or the drain active region includes a planar active region; may form a channel active region between the source active region and the drain active region and extending above the substrate; may form a gate structure over the channel active region and wrapping around the channel active region on at least three sides of the channel active region; and/or may form a gate STI region between the channel active region and the drain active region, and extending into the substrate. Source/drain region(s) may refer to a source or a drain, individually or collectively dependent upon the context.

As another example, one or more of the semiconductor processing tools 102-112 and/or the wafer/die transport tool 114 may form a first source/drain region including a source active region that extends above a substrate of a semiconductor device; may form a second source/drain region including a drain active region that extends above the substrate, where at least one of the source active region or the drain active region includes a planar active region; may form a channel active region between the source active region and the drain active region and extending above the substrate, where the drain active region and the channel active region are directly connected; and/or may form a gate structure over the channel active region and wrapping around the channel active region on at least three sides of the channel active region.

As another example, one or more of the semiconductor processing tools 102-112 and/or the wafer/die transport tool 114 may etch a substrate and in a device region of a semiconductor device to form a source active region; may etch the substrate in the device region to form a drain active region; may etch the substrate in the device region to form a channel active region, where the channel active region is between the source active region and the drain active region, and where at least one of the source active region, the drain active region, or the channel active region includes a planar active region; and/or may forming a gate structure over at least three sides of the channel active region.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

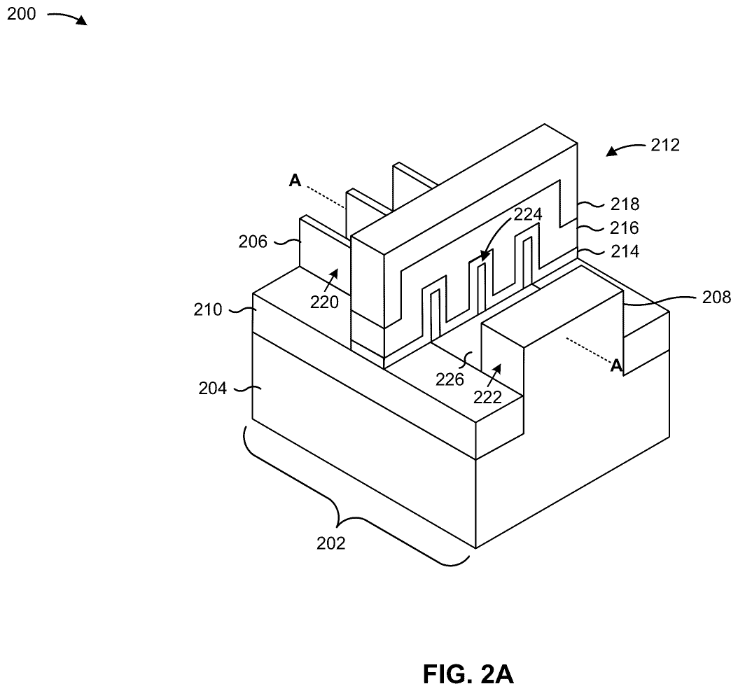

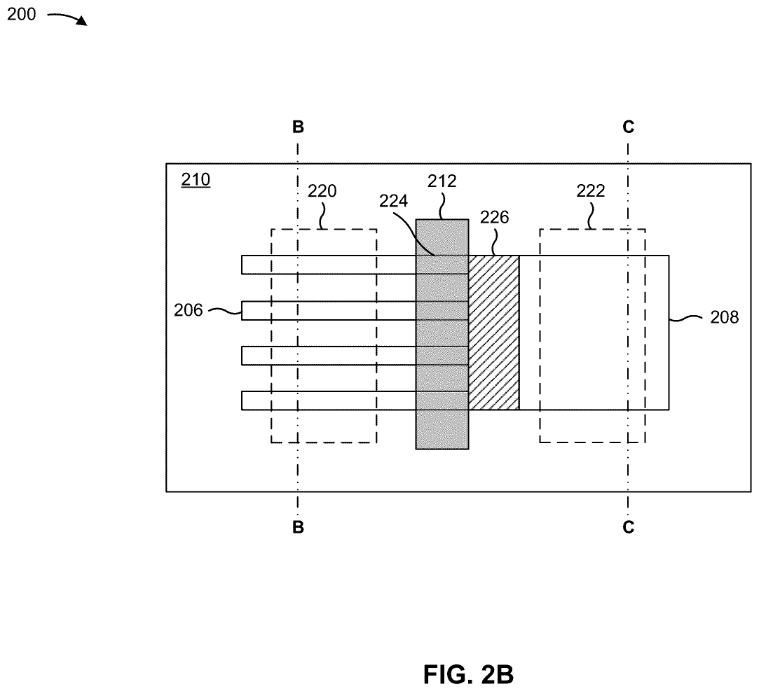

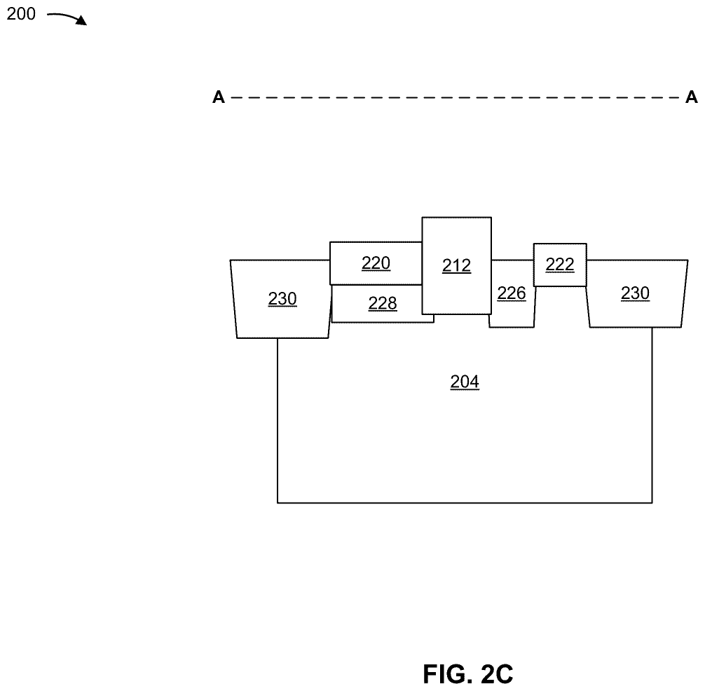

FIGS. 2A-2C are diagrams of an example semiconductor device 200 described herein. In particular, FIGS. 2A-2C illustrate an example device region 202 of the semiconductor device 200 in which one or more high-voltage transistors or other devices are included. The high-voltage transistors may include high-voltage fin-based transistors, such as high-voltage fin field effect transistors (finFETs), high-voltage nanostructure transistors, and/or other types of high-voltage transistors. In some implementations, the device region 202 includes a p-type metal oxide semiconductor (PMOS) region, an n-type metal oxide semiconductor (NMOS) region, a complementary metal oxide semiconductor (CMOS) region, and/or another type of device region.

The high-voltage transistors may be configured to operate based on a relatively high drain voltage (V_{d}) (e.g., relative to a low-voltage fin-based transistor). As an example, a high-voltage transistor included in the device region 202 may operate in a drain voltage range of approximately 0 volts to approximately 5 volts, whereas a low-voltage transistor might operate in a drain voltage range of approximately 0 volts to approximately 1.8 volts.

The semiconductor device 200 includes a substrate 204. The substrate 204 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, or another type of semiconductor substrate. The substrate 204 may include a round/circular substrate having an approximately 200 mm diameter, an approximately 300 mm diameter, or another diameter, such as 450 mm, among other examples. The substrate 204 may alternatively be any polygonal, square, rectangular, curved, or otherwise non-circular workpiece, such as a polygonal substrate. In some implementations, the substrate 204 is doped with one or more types of dopants to form one or more dopant wells in the substrate 204. For example, the substrate 204 in the device region 202 may be doped with n-type dopants to form an n-type well in the substrate 204, and/or may be doped with p-type dopants to form a p-type well in the substrate 204.

An example of a high-voltage transistor is illustrated in FIGS. 2A-2C. One or more active regions of the high-voltage transistor may be included above and/or may extend above the substrate 204. An active region also may be referred to as an operation domain (OD), and may include a portion of the semiconductor device 200 that is used in active operation of the high-voltage transistor. A source/drain active region 206 and a source/drain active region 208 may each extend above the substrate 204 and may provide active regions by which current may flow from a source of the high-voltage transistor to a drain portion of the high-voltage transistor (e.g., through one or more channels of the high-voltage transistor). For example, the source/drain active region 206 may be a source active region and the source/drain active region 208 may be a drain active region.

The source/drain active region 206 may include a plurality of fin structures or fin active regions. In some implementations, the fin active regions include silicon (Si) materials or another elementary semiconductor material such as germanium (Ge). In some implementations, the fin active regions include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof. In some implementations, the fin active regions are doped using n-type and/or p-type dopants.

The drain active region 208 may include a planar (or approximately planar) structure or planar active region. The planar active region provides reduced interface surface area (e.g., relative to the fin active regions of the source/drain active region 206) between the drain active region 208 and dielectric layers surrounding the drain active region 208, which reduces charge trapping in the drain active region 208. In some implementations, the reduced occurrence of charge trapping in the high-voltage transistor provided by the planar active region(s) may result in lower linear drain current (I_{dlin}) degradation. For example, the reduced occurrence of charge trapping in the high-voltage transistor provided by the planar active region(s) may result in approximately 0.50% to approximately 0.70% I_{dlin} degradation relative to 5.70% to 6.50% for another high-voltage transistor with a fully fin-based active region.

In some implementations, the planar active region includes silicon (Si) materials or another elementary semiconductor material such as germanium (Ge). In some implementations, the planar active region includes an alloy semiconductor material such as silicon germanium (SiGe), gallium arsenide phosphide (GaAsP), aluminum indium arsenide (AlinAs), aluminum gallium arsenide (AlGaAs), gallium indium arsenide (GaInAs), gallium indium phosphide (GaInP), gallium indium arsenide phosphide (GaInAsP), or a combination thereof. In some implementations, the planar active region are doped using n-type and/or p-type dopants.

The dielectric layers may include STI regions 210 above the substrate 204 and surrounding the drain active region 208 on two or more sides of the drain active region 208. The dielectric layers may also include one or more ILD layers (not shown for clarity) above the STI regions 210, above the source/drain active region 206, and/or the drain active region 208. The STI regions 210 may electrically isolate adjacent active regions in the semiconductor device 200. The STI regions 210 may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. The STI regions 210 may include a multi-layer structure, for example, having one or more liner layers.

A gate structure 212 (or a plurality of gate structures 212) is included in the device region 202. The gate structure 212 may be orientated approximately perpendicular to the fin active regions of the source/drain active region 206. The gate structure 212 may be located between the fin active regions of the source/drain active region 206 and the planar active region of the drain active region 208. The gate structure 212 may include a gate dielectric layer 214, a gate electrode layer 216, a capping layer 218, and/or another layer. In some implementations, the gate structure 212 further includes one or more spacer layers and/or another suitable layer. The various layers of the gate structure 212 may be formed by suitable deposition techniques and patterned by suitable photolithography and etching techniques.

In some implementations, the gate structure 212 is a dummy gate structure or a placeholder gate structure. The term, “dummy”, as described here, refers to a sacrificial structure which will be removed in a later stage and will be replaced with another structure, such as a high dielectric constant (high-k) dielectric and metal gate structure in a replacement gate process. The replacement gate process refers to manufacturing a gate structure at a later stage of the overall gate manufacturing process. Accordingly, the configuration of the semiconductor device 200 illustrated in FIG. 2A may include an intermediate configuration, and additional semiconductor processing operations may be performed for the semiconductor device 200 to further process the semiconductor device 200.

The gate dielectric layer 214 may include a dielectric oxide layer. The dielectric oxide layer may be formed by chemical oxidation, thermal oxidation, ALD, CVD, and/or other suitable methods. The gate electrode layer 216 may include a poly-silicon material or another suitable material. The gate electrode layer 216 may be formed by suitable deposition processes such as LPCVD or PECVD, among other examples. The capping layer 218 may include any material suitable to pattern the gate electrode layer 216 with particular features/dimensions on the substrate 204.

Source/drain regions are included on opposing sides of the gate structure 212. The source/drain regions include regions in the device region 202 that include and/or are configured to operate as a source or a drain of a high-voltage transistor of the semiconductor device 200. For example, a source/drain region 220 may be included in and/or above the fin active regions of the source/drain active region 206. As another example, a source/drain region 222 may be included in and/or above the planar active region of the drain active region 208. The source/drain regions in the device region 202 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the device region 202 may include high-voltage PMOS transistors that include p-type source/drain regions, high-voltage NMOS transistors that include n-type source/drain regions, and/or other types of high-voltage transistors.

As further shown in FIG. 2A, a channel active region 224 is included under the gate structure 212. The channel active region 224 may include a plurality of fin active regions. The gate structure 212 may wrap around each of the plurality of fin active regions on at least three sides of the plurality of fin active regions. The plurality of fin active regions of the channel active region 224 may be directly connected with (e.g., in physical contact with) the plurality of fin active regions of the source/drain active region 206. In some implementations, the plurality of fin active regions of the channel active region 224 and the plurality of fin active regions of the source/drain active region 206 may be formed in the same process or same set of processes. In some implementations, the plurality of fin active regions of the channel active region 224 and the plurality of fin active regions of the source/drain active region 206 may be the same plurality of fin active regions, where the channel active region 224 corresponds to portions of the plurality of fin active regions under the gate structure 212.

As further shown in FIG. 2A, a gate STI region 226 may be included in and/or may extend into the substrate 204. The gate STI region 226 may be included between the gate structure 212 and the drain active region 208, and between the channel active region 224 and the drain active region 208, to increase the distance between the gate structure 212 and the drain active region 208 and to provide increased electrical isolation between the gate structure 212 and the drain active region 208. The increased distance and increased electrical isolation may enable the high-voltage transistor to operate at higher drain voltages relative to a low-voltage fin-based transistor. The gate STI region 226 may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material.

FIG. 2B illustrates a top-down view of the device region 202 of the semiconductor device 200. The high-voltage transistor in the device region 202 of the semiconductor device 200 may include the source/drain region 220 that includes the source active region 206 that extends above the substrate 204. The high-voltage transistor in the device region 202 of the semiconductor device 200 may include the source/drain region 222 that includes the drain active region 208 that extends above the substrate 204. The high-voltage transistor in the device region 202 of the semiconductor device 200 may include the channel active region 224 between the source/drain active region 206 and the drain active region 208. The high-voltage transistor in the device region 202 of the semiconductor device 200 may include the gate structure 212 over the channel active region 224. The gate structure 212 may be between the source/drain active region 206 and the drain active region 208, and may wrap around the channel active region 224 on at least three sides of the channel active region 224. The high-voltage transistor in the device region 202 of the semiconductor device 200 may include the gate STI region 226 between the channel active region 224 and the drain active region 208. The gate STI region 226 may extend into the substrate 204. The source/drain active region 206 and the drain active region 208 may be at least partially surrounded by one or more STI regions 210.

As further shown in FIG. 2B, the source/drain active region 206 may include a plurality of fin active regions that extend above the substrate 204. The drain active region 208 may include a planar active region that extends above the substrate 204. The channel active region 224 may include a plurality of fin active regions that extend above the substrate 204. The fin active regions of the source/drain active region 206 and the channel active region 224 may include elongated fin structures that extend in a direction that is approximately perpendicular with the gate structure 212. The elongated fin structures are longer and narrower than the planar active region. The planar active region may be approximately square shaped, approximately rectangular shaped, approximately circular shaped, and/or another shape. A ratio between a length to a width of each of the elongated fin structures is greater relative to a ratio between a length to a width of the planar active region. The STI regions 210 are included between the plurality of fin active regions, whereas the planar active region is a singular structure and the STI regions 210 are around only the perimeter of the planar active region.

FIG. 2C illustrates a cross-section view along line A-A in FIG. 2A. The cross-section view of FIG. 2C is in a plane along the channel active region 224 between the source/drain active region 206 and the drain active region 208. As shown in FIG. 2C, the high-voltage transistor in the device region 202 of the semiconductor device 200 may further include a well region 228 under the source/drain region 220. The well region 228 may include a p-well region, an n-well region, or a combination thereof. The well region 228 may facilitate the flow of current from the source/drain region 220 to the source/drain region 222 through the channel active region 224 and under the gate STI region 226. The substrate 204 may also include a another well region, which may be doped with an opposite type of dopants relative to the well region 228.

High-voltage STI regions 230 may be included in the substrate 204. The high-voltage STI regions 230 may configured to provide additional electrical isolation between adjacent high-voltage transistors in the device region 202. A high-voltage STI region 230 may be included on a side of the source/drain region 220 opposing another side of the source/drain region 220 that is facing the gate structure 212. Another high-voltage STI region 230 may be included on a side of the source/drain region 222 opposing another side of the source/drain region 222 that is facing the gate STI region 226.

As indicated above, FIGS. 2A-2C are provided as examples. Other examples may differ from what is described with regard to FIG. 2A-2C.

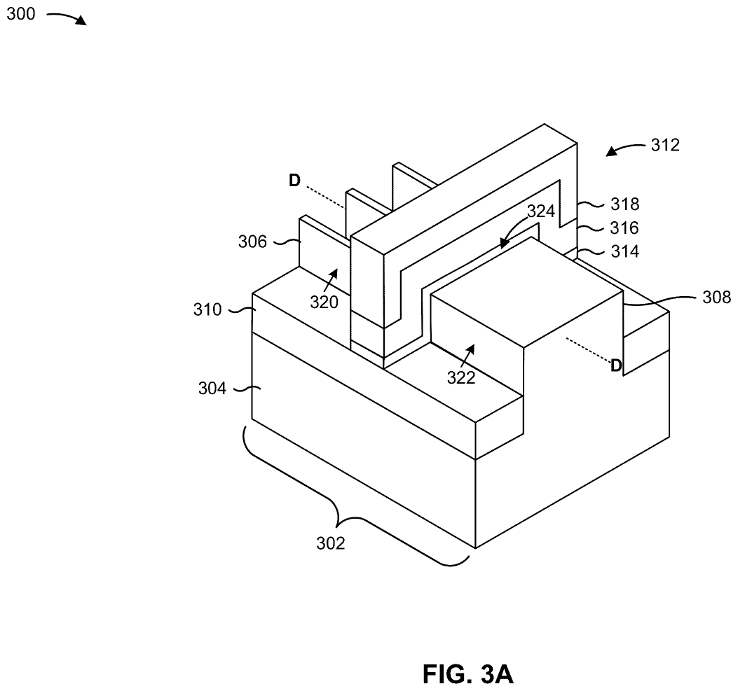

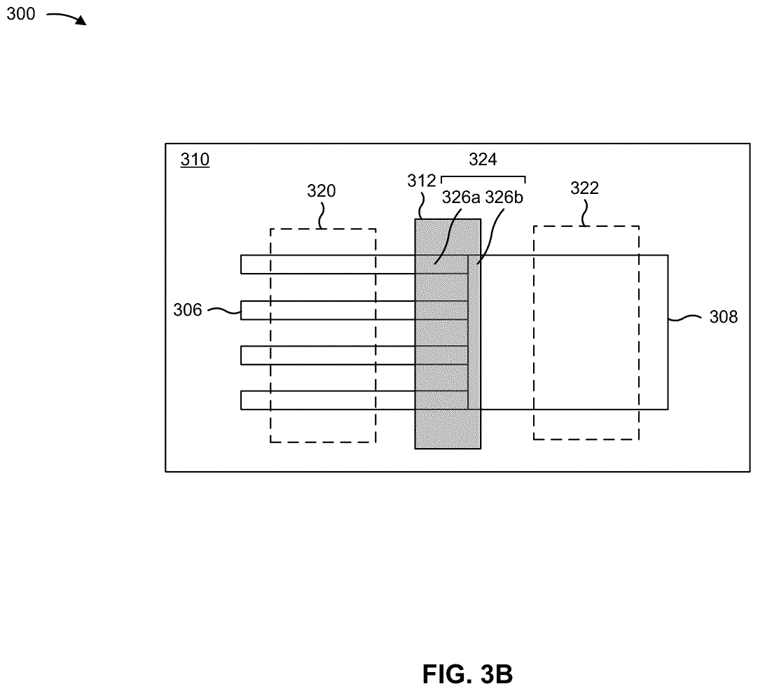

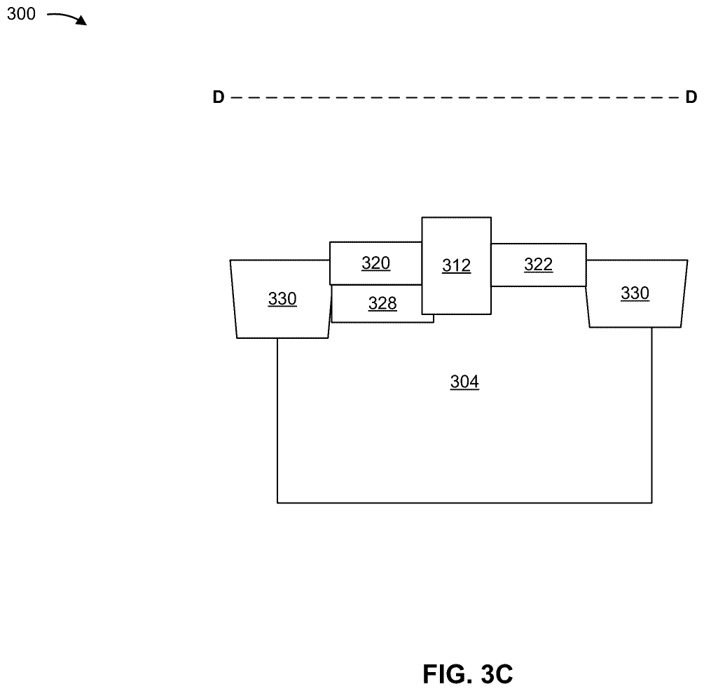

FIGS. 3A-3C are diagrams of an example semiconductor device 300 described herein. In particular, FIGS. 3A-3C illustrate an example device region 302 of the semiconductor device 300 in which one or more high-voltage transistors or other devices are included. The high-voltage transistors may include high-voltage fin-based transistors, such as high-voltage finFETs, high-voltage nanostructure transistors, and/or other types of high-voltage transistors. In some implementations, the device region 302 includes a PMOS region, an NMOS region, a CMOS region, and/or another type of device region.

As shown in FIG. 3A, an example high-voltage transistor in the device region 302 of the semiconductor device 300 may include a substrate 304, a source/drain active region 306, a source/drain active region 308, STI regions 310, a gate structure 312 (which may include a gate dielectric layer 314, a gate electrode layer 316, a capping layer 318, and/or another layer), a source/drain region 320, a source/drain region 322, and a channel active region 324. In some implementations, the source/drain active region 306 may include a source active region and the source/drain region 308 may include a drain active region. These structures may be similar to the corresponding structures described above in connection with FIG. 2A, except that a gate STI region is omitted from the semiconductor device 300. Instead, the planar active region of the source/drain active region 308 is directly connected with (and/or physically contacting) the channel active region 324. Omitting the gate STI region may enable the physical side of the high-voltage transistor in the device region 302 of the semiconductor device 300 to be reduced.

FIG. 3B illustrates a top-down view of the device region 302 of the semiconductor device 300. The high-voltage transistor in the device region 302 of the semiconductor device 300 may include the source/drain region 320 that includes a source active region 306. The high-voltage transistor in the device region 302 of the semiconductor device 300 may include a source/drain region 322 that includes a drain active region 308. The high-voltage transistor in the device region 302 of the semiconductor device 300 may include a channel active region 324 between the source/drain active region 306 and the source/drain active region 308. The high-voltage transistor in the device region 302 of the semiconductor device 300 may include a gate structure 312 over the channel active region 324. The gate structure 312 may be between the source/drain active region 306 and the source/drain active region 308, and may wrap around the channel active region 324 on at least three sides of the channel active region 324. The source/drain active region 306 and the source/drain active region 308 may be at least partially surrounded by one or more STI regions 310.

As further shown in FIG. 3B, the source/drain active region 306 may include a plurality of fin active regions (e.g., fin source active regions) that extend above the substrate 304. The source/drain active region 308 may include a planar active region (e.g., a planar drain active region) that extends above the substrate 304. The channel active region 324 may include portions 326a of a plurality of the fin active regions under the gate structure 312 and a portion 326b of the planar active region under the gate structure 312. The portions 326a of the plurality of active fin regions under the gate structure 312 and the portion 326b of the planar active region under the gate structure 312 may be directly connected and/or in physical contact. The gate structure 312 may wrap around the portions 326a of the plurality of active fin regions under the gate structure 312 and the portion 326b of the planar active region under the gate structure 312.

The plurality of fin active regions of the source/drain active region 306 and the channel active region 324 may include elongated fin structures that extend in a direction that is approximately perpendicular with the gate structure 312. The elongated fin structures are longer and narrower than the planar active region of the source/drain active region 308 and of the channel active region 324. The planar active region may be approximately square shaped, approximately rectangular shaped, approximately circular shaped, and/or another shape. A ratio between a length to a width of each of the elongated fin structures is greater relative to a ratio between a length to a width of the planar active region. The STI regions 310 are included between the plurality of fin active regions, whereas the planar active region is a singular structure and the STI regions 310 are around only the perimeter of the planar active region.

FIG. 3C illustrates a cross-section view along line C-C in FIG. 3A. The cross-section view of FIG. 3C is in a plane along the channel active region 324 between the source/drain active region 306 and the source/drain active region 308. As shown in FIG. 3C, the high-voltage transistor in the device region 302 of the semiconductor device 300 may further include a well region 328 under the source/drain region 320. The well region 328 may include a p-well region, an n-well region, or a combination thereof. The well region 328 may facilitate the flow of current from the source/drain region 320 to the source/drain region 322 through the channel active region 324. The substrate 304 may also include a another well region, which may be doped with an opposite type of dopants relative to the well region 328.

High-voltage STI regions 330 may be included in the substrate 304. The high-voltage STI regions 330 may configured to provide additional electrical isolation between adjacent high-voltage transistors in the device region 302. A high-voltage STI region 330 may be included on a side of the source/drain region 320 opposing another side of the source/drain region 320 that is facing the gate structure 312. Another high-voltage STI region 330 may be included on a side of the source/drain region 322 opposing another side of the source/drain region 322 that is facing the gate structure 312.

As indicated above, FIGS. 3A-3C are provided as examples. Other examples may differ from what is described with regard to FIG. 3A-3C.

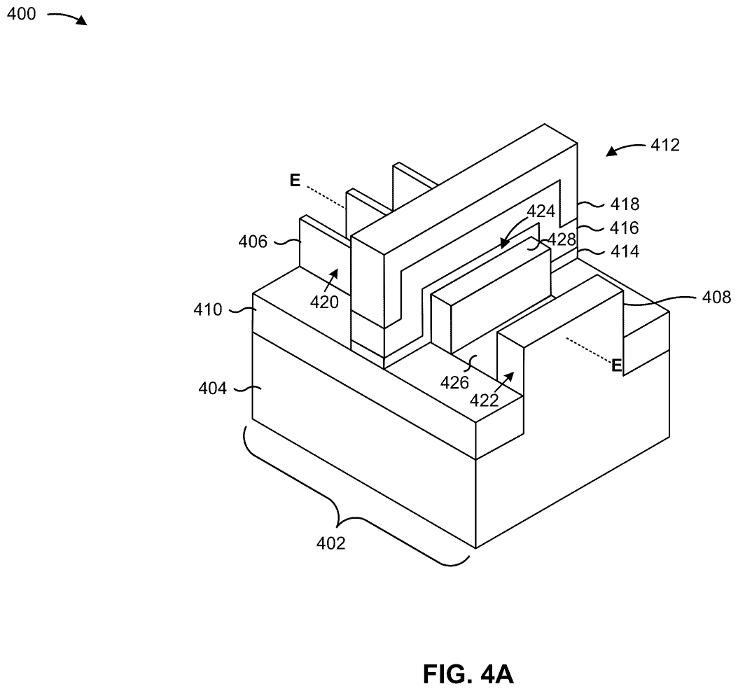

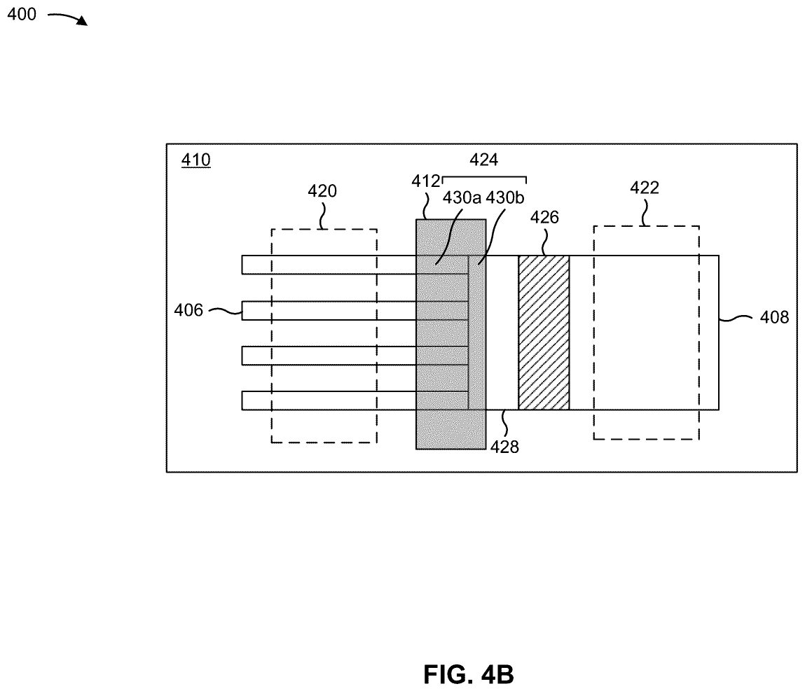

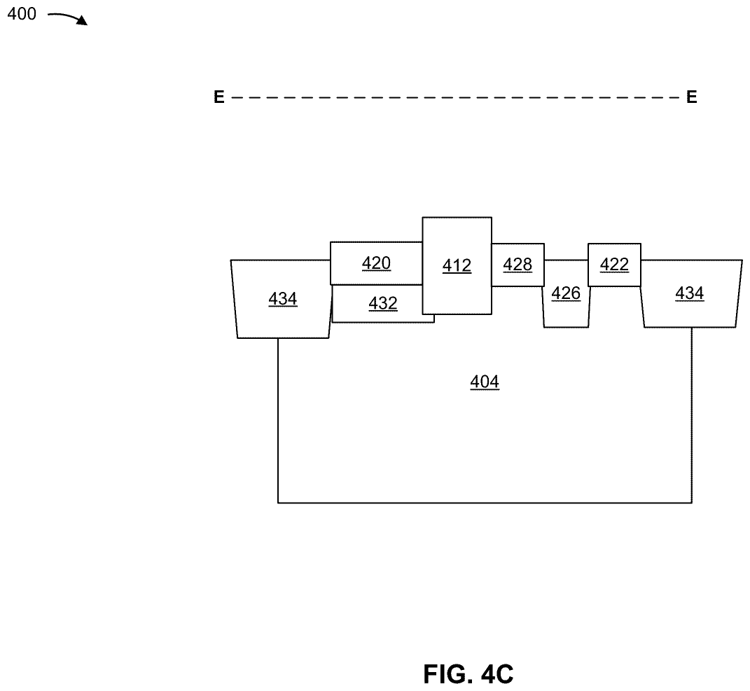

FIGS. 4A-4C are diagrams of an example semiconductor device 400 described herein. In particular, FIGS. 4A-4C illustrate an example device region 402 of the semiconductor device 400 in which one or more high-voltage transistors or other devices are included. The high-voltage transistors may include high-voltage fin-based transistors, such as high-voltage finFETs, high-voltage nanostructure transistors, and/or other types of high-voltage transistors. In some implementations, the device region 402 includes a PMOS region, an NMOS region, a CMOS region, and/or another type of device region.

As shown in FIG. 4A, an example high-voltage transistor in the device region 402 of the semiconductor device 400 may include a substrate 404, a source/drain active region 406, a source/drain active region 408, STI regions 410, a gate structure 412 (which may include a gate dielectric layer 414, a gate electrode layer 416, a capping layer 418, and/or another layer), a source/drain region 420, a source/drain region 422, a channel active region 424, and a gate STI region 426. These structures may be similar to the corresponding structures described above in connection with FIG. 2A. In some implementations, the source/drain active region 406 includes a source active region and the source/drain active region 408 includes a drain active region.

As further shown in FIG. 4A, the high-voltage transistor in the device region 402 of the semiconductor device 400 may further include a planar extension region 428 that is directly connected with and/or physically contacting the fin active regions of the channel active region 424. The planar extension region 428 includes another planar active region that is between the gate structure 412 (and at least partially under the gate structure 412) and the gate STI region 426. Accordingly, the gate STI region 426 is between the planar extension region 428 and the planar active region of the source/drain active region 408. The planar extension region 428 may be formed by etching the substrate 404 to form the planar extension region 428 in a similar manner as the source/drain active region 406, the source/drain active region 408, and the channel active region 424.

FIG. 4B illustrates a top-down view of the device region 402 of the semiconductor device 400. The high-voltage transistor in the device region 402 of the semiconductor device 400 may include the source/drain region 420 that includes a source/drain active region 406 that extends above the substrate 404. The high-voltage transistor in the device region 402 of the semiconductor device 400 may include a source/drain region 422 that includes a source/drain active region 408 that extends above the substrate 404. The high-voltage transistor in the device region 402 of the semiconductor device 400 may include the channel active region 424 between the source/drain active region 406 and the source/drain active region 408. The channel active region 424 extends above the substrate 404. The high-voltage transistor in the device region 402 of the semiconductor device 400 may include a gate structure 412 over the channel active region 424. The gate structure 412 may be between the source/drain active region 406 and the source/drain active region 408, and may wrap around the channel active region 424 on at least three sides of the channel active region 424. The source/drain active region 406 and the source/drain active region 408 may be at least partially surrounded by one or more STI regions 410. The high-voltage transistor in the device region 402 of the semiconductor device 400 may include the planar extension region 428 that extends above the substrate 404 and is included between the channel active region 424.

As further shown in FIG. 4B, the source/drain active region 406 may include a plurality of fin active regions that extend above the substrate 404. The source/drain active region 408 may include a planar active region that extends above the substrate 404. The planar extension region 428 may include another planar active region that extends above the substrate 404 and that is not in direct contact with the planar active region of the source/drain active region 408. The planar active region of the planar extension region 428 and the planar active region of the source/drain active region 408 may be spaced apart by the gate STI region 426. Thus, the gate STI region 426 may be adjacent to the planar extension region 428 on a first side of the gate STI region 426, and may be adjacent to the source/drain active region 408 on a second side of the gate STI region 426 opposing the first side.

The channel active region 424 may include portions 430a of a plurality of the fin active regions under the gate structure 412 and a portion 430b of the planar active region of the planar extension region 428 under the gate structure 412. The portions 430a of the plurality of active fin regions under the gate structure 412 and the portion 430b of the planar active region of the planar extension region 428 under the gate structure 412 may be directly connected and/or in direct physical contact. The gate structure 412 may wrap around the portions 430a of the plurality of active fin regions under the gate structure 412 and the portion 430b of the planar active region of the planar extension region 428 under the gate structure 412. Another portion of the planar active region of the planar extension region 428 may extend outward from gate structure 412 (and toward the gate STI region 426) and is not under the gate structure 412.

The plurality of fin active regions of the source/drain active region 406 and the channel active region 424 may include elongated fin structures that extend in a direction that is approximately perpendicular with the gate structure 412. The elongated fin structures are longer and narrower than the planar active regions of the source/drain active region 408, of the channel active region 424, and of the planar extension region 428. The planar active regions may be approximately square shaped, approximately rectangular shaped, approximately circular shaped, and/or another shape. A ratio between a length to a width of each of the elongated fin structures is greater relative to a ratio between a length to a width of the planar active regions. The STI regions 410 are included between the plurality of fin active regions, whereas each of the planar active regions is a singular structure and the STI regions 410 are around only the perimeter (or a portion of the perimeter) of the planar active regions.

FIG. 4C illustrates a cross-section view along line E-E in FIG. 4A. The cross-section view of FIG. 4C is in a plane along the channel active region 424 between the source/drain active region 406 and the source/drain active region 408. As shown in FIG. 4C, the high-voltage transistor in the device region 402 of the semiconductor device 400 may further include a well region 432 under the source/drain region 420. The well region 432 may include a p-well region, an n-well region, or a combination thereof. The well region 432 may facilitate the flow of current from the source/drain region 420 to the source/drain region 422 through the channel active region 424, through the planar extension region 428, and under the gate STI region 426. The substrate 404 may also include a another well region, which may be doped with an opposite type of dopants relative to the well region 432.

High-voltage STI regions 434 may be included in the substrate 404. The high-voltage STI regions 434 may configured to provide additional electrical isolation between adjacent high-voltage transistors in the device region 402. A high-voltage STI region 434 may be included on a side of the source/drain region 420 opposing another side of the source/drain region 420 that is facing the gate structure 412. Another high-voltage STI region 434 may be included on a side of the source/drain region 422 opposing another side of the source/drain region 422 that is facing the gate STI region 426.

As indicated above, FIGS. 4A-4C are provided as examples. Other examples may differ from what is described with regard to FIG. 4A-4C.

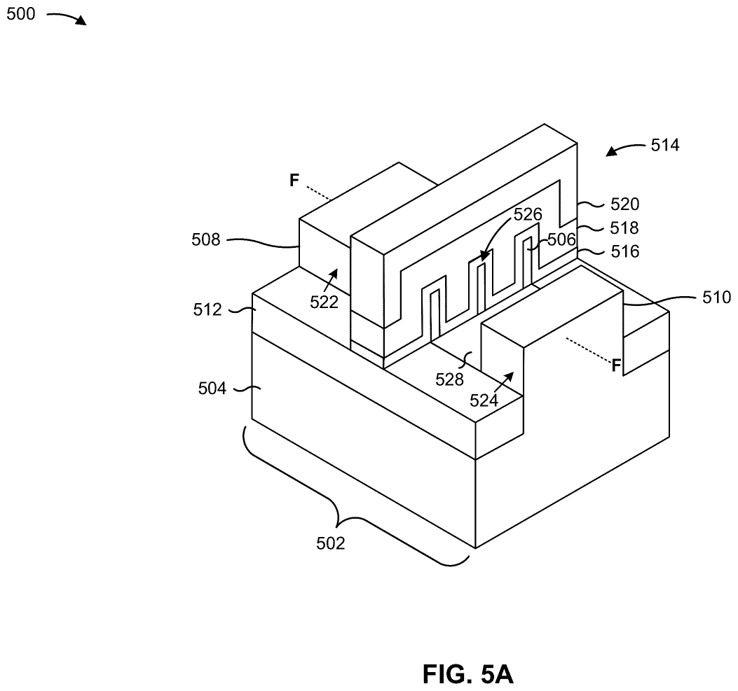

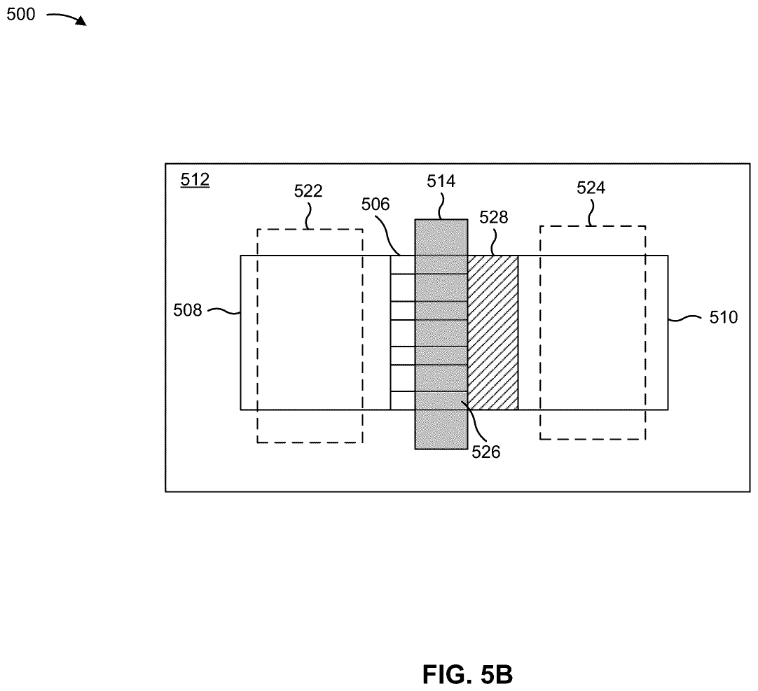

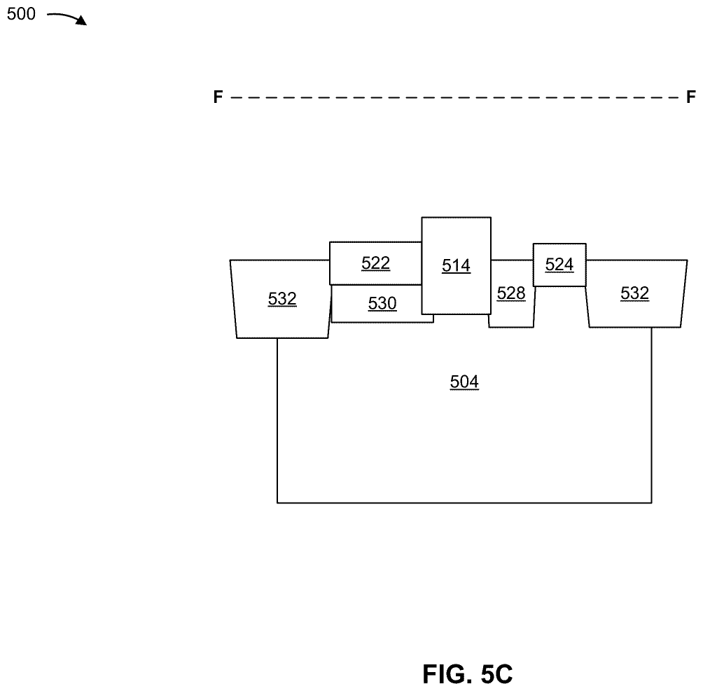

FIGS. 5A-5C are diagrams of an example semiconductor device 500 described herein. In particular, FIGS. 5A-5C illustrate an example device region 502 of the semiconductor device 500 in which one or more high-voltage transistors or other devices are included. The high-voltage transistors may include high-voltage fin-based transistors, such as high-voltage finFETs, high-voltage nanostructure transistors, and/or other types of high-voltage transistors. In some implementations, the device region 502 includes a PMOS region, an NMOS region, a CMOS region, and/or another type of device region.

FIG. 5A illustrates an example high-voltage transistor in the device region 502 of the semiconductor device 500. As shown in FIG. 5A, the structures of the high-voltage transistor in the device region 502 of the semiconductor device 500 may be similar to the corresponding structures described above in connection with FIG. 2A. However, the high-voltage transistor in the device region 502 of the semiconductor device 500 instead includes a planar active region for the source active region as opposed to a plurality of fin active regions. The channel active region, however, still includes a plurality of fin active regions.

As shown in FIG. 5A, the high-voltage transistor in the device region 502 of the semiconductor device 500 may include a substrate 504, a plurality of fin active regions 506, a source/drain active region 508, a source/drain active region 510, STI regions 512, a gate structure 514 (which may include a gate dielectric layer 516, a gate electrode layer 518, a capping layer 520, and/or another layer), a source/drain region 522, a source/drain region 524, and a channel active region 526 corresponding to portions of the plurality of fin active regions 506 under the gate structure 514. In some implementations, the source/drain active region 508 may include a source active region and the source/drain active region 510 may include a drain active region.

FIG. 5B illustrates a top-down view of the device region 502 of the semiconductor device 500. The high-voltage transistor in the device region 502 of the semiconductor device 500 may include the source/drain region 522 that includes the source/drain active region 508. The high-voltage transistor in the device region 502 of the semiconductor device 500 may include the source/drain region 524 that includes the source/drain active region 510. The high-voltage transistor in the device region 502 of the semiconductor device 500 may include the channel active region 526 between the source/drain active region 508 and the source/drain active region 510. The high-voltage transistor in the device region 502 of the semiconductor device 500 may include the gate structure 514 over the channel active region 526. The gate structure 514 may be between the source/drain active region 508 and the source/drain active region 510, and may wrap around the channel active region 524 on at least three sides of the channel active region 526. The high-voltage transistor in the device region 502 of the semiconductor device 500 may include the gate STI region 528 between the channel active region 526 and the drain active region 510. The gate STI region 528 may extend into the substrate 504. The source/drain active region 508 and the source/drain active region 510 may be at least partially surrounded by one or more STI regions 512.

As further shown in FIG. 5B, the source/drain active region 508 may include planar active region (e.g., a planar source active region) that extends above the substrate 504. The source/drain active region 510 may include a planar active region (e.g., a planar drain active region) that extends above the substrate 504. The channel active region 526 may include the plurality of fin active regions 506 (e.g., fin channel active regions) that extend above the substrate 504. The planar active region of the source/drain active region 508 and the plurality of fin active regions 506 of the channel active region 526 may be directly connected and/or in direct physical contact. Portions of the plurality of fin active regions 506 of the channel active region 526 may be located under the gate structure 514, and other portions of the plurality of fin active regions 506 of the channel active region 526 may extend outward from the gate structure 514 (and toward the planar active region of the source/drain active region 508) and are not under the gate structure 514. The portions of the plurality of fin active regions 506 of the channel active region 526 may be adjacent to the gate STI region 528 on a first side of the gate STI region 528. The planar active region of the source/drain active region 510 may be located on a second side of the gate STI region 528 opposing the first side. The gate structure 514 may wrap around the portions of the plurality of fin active regions 506 of the channel active region 526 under the gate structure 514 on at least three sides of the plurality of fin active regions 506.

The fin active regions 506 of the channel active region 526 may include elongated fin structures that extend in a direction that is approximately perpendicular with the gate structure 514. The elongated fin structures are narrower than the planar active regions of the source/drain active region 508 and the source/drain active region 510. The planar active regions of the source/drain active region 508 and the source/drain active region 510 may be approximately square shaped, approximately rectangular shaped, approximately circular shaped, and/or another shape. A ratio between a length to a width of each of the elongated fin structures is greater relative to a ratio between a length to a width of the planar active regions. The STI regions 512 are included between the plurality of fin active regions 506, whereas the planar active region is a singular structure and the STI regions 512 are around only the perimeter of the planar active regions.

FIG. 5C illustrates a cross-section view along line F-F in FIG. 5A. The cross-section view of FIG. 5C is in a plane along the channel active region 526 between the source/drain active region 508 and the source/drain active region 510. As shown in FIG. 5C, the high-voltage transistor in the device region 502 of the semiconductor device 500 may further include a well region 530 under the source/drain region 522. The well region 530 may include a p-well region, an n-well region, or a combination thereof. The well region 530 may facilitate the flow of current from the source/drain region 522 to the source/drain region 524 through the channel active region 526 and under the gate STI region 528. The substrate 504 may also include a another well region, which may be doped with an opposite type of dopants relative to the well region 530.

High-voltage STI regions 532 may be included in the substrate 504. The high-voltage STI regions 532 may configured to provide additional electrical isolation between adjacent high-voltage transistors in the device region 502. A high-voltage STI region 532 may be included on a side of the source/drain region 522 opposing another side of the source/drain region 522 that is facing the gate structure 514. Another high-voltage STI region 532 may be included on a side of the source/drain region 524 opposing another side of the source/drain region 524 that is facing the gate STI region 528.

As indicated above, FIGS. 5A-5C are provided as examples. Other examples may differ from what is described with regard to FIG. 5A-5C.

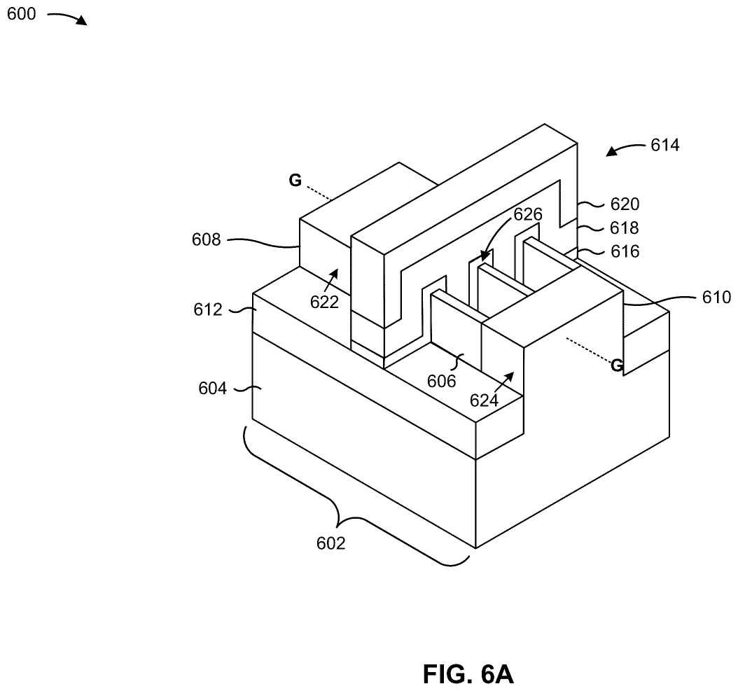

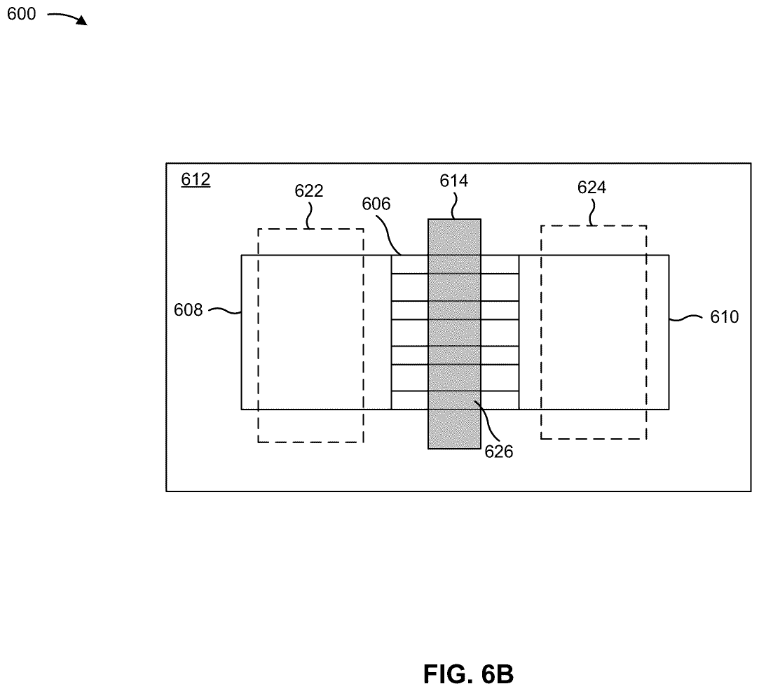

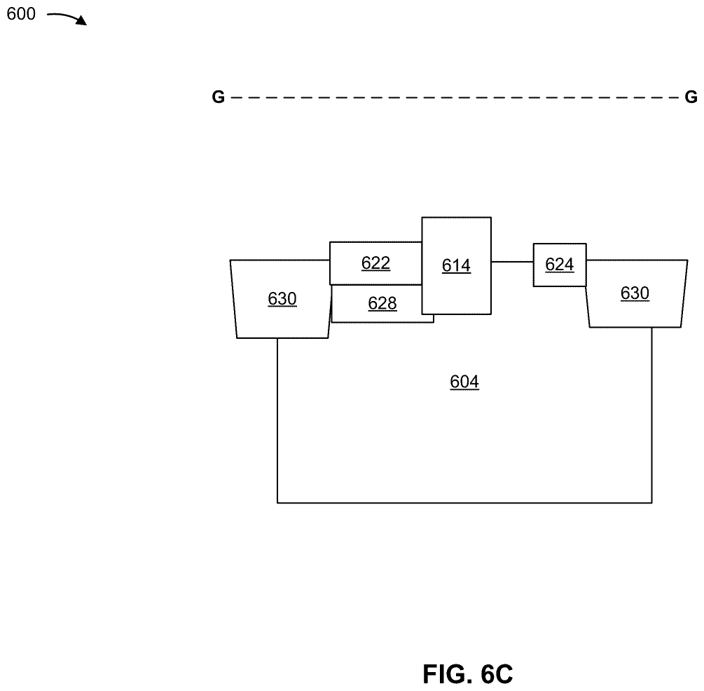

FIGS. 6A-6C are diagrams of an example semiconductor device 600 described herein. In particular, FIGS. 6A-6C illustrate an example device region 602 of the semiconductor device 600 in which one or more high-voltage transistors or other devices are included. The high-voltage transistors may include high-voltage fin-based transistors, such as high-voltage finFETs, high-voltage nanostructure transistors, and/or other types of high-voltage transistors. In some implementations, the device region 602 includes a PMOS region, an NMOS region, a CMOS region, and/or another type of device region.

FIG. 6A illustrates an example high-voltage transistor in the device region 602 of the semiconductor device 600. As shown in FIG. 6A, the structures of the high-voltage transistor in the device region 602 of the semiconductor device 600 may be similar to the corresponding structures described above in connection with FIG. 5A. However, a gate STI region is omitted from the high-voltage transistor in the device region 602 of the semiconductor device 600.

As shown in FIG. 6A, the high-voltage transistor in the device region 602 of the semiconductor device 600 may include a substrate 604, a plurality of fin active regions 606, a source/drain active region 608, a source/drain active region 610, STI regions 612, a gate structure 614 (which may include a gate dielectric layer 616, a gate electrode layer 618, a capping layer 620, and/or another layer), a source/drain region 622, a source/drain region 624, and a channel active region 626 corresponding to portions of the plurality of fin active regions 606 under the gate structure 614. In some implementations, the source/drain active region 608 may include a source active region and the source/drain active region 610 may include a drain active region.

FIG. 6B illustrates a top-down view of the device region 602 of the semiconductor device 600. The high-voltage transistor in the device region 602 of the semiconductor device 600 may include the source/drain region 622 that includes the source/drain active region 608. The high-voltage transistor in the device region 602 of the semiconductor device 600 may include the source/drain region 624 that includes the source/drain active region 610. The high-voltage transistor in the device region 602 of the semiconductor device 600 may include the channel active region 626 between the source/drain active region 608 and the source/drain active region 610. The high-voltage transistor in the device region 602 of the semiconductor device 600 may include the gate structure 614 over the channel active region 626. The gate structure 614 may be between the source/drain active region 608 and the source/drain active region 610, and may wrap around the channel active region 624 on at least three sides of the channel active region 626. The source/drain active region 608 and the source/drain active region 610 may be at least partially surrounded by one or more STI regions 612.

As further shown in FIG. 6B, the source/drain active region 608 may include planar active region that extends above the substrate 604. The source/drain active region 610 may include a planar active region that extends above the substrate 604. The channel active region 626 may include the plurality of fin active regions 606 that extend above the substrate 604. First portions of the plurality of fin active regions 606 of the channel active region 626 may be located under the gate structure 614 such that the gate structure 614 wraps around the first portions of the plurality of fin active regions 606 on at least three sides of the first portions of the plurality of fin active regions 606. Second portions of the plurality of fin active regions 606 may extend outward from the gate structure 614 (and toward the source/drain active region 608) such that the second portions of the plurality of fin active regions 606 are not under the gate structure 614. Third portions of the plurality of fin active regions 606 may extend outward from the gate structure 614 (and toward the source/drain active region 610) such that the third portions of the plurality of fin active regions 606 are not under the gate structure 614.

The planar active region of the source/drain active region 608 and the second portions of the plurality of fin active regions 606 of the channel active region 626 may be directly connected and/or in direct physical contact. The planar active region of the drain active region 610 and the third portions of the plurality of fin active regions 606 of the channel active region 626 may be directly connected and/or in direct physical contact.

The fin active regions 606 of the channel active region 626 may include elongated fin structures that extend in a direction that is approximately perpendicular with the gate structure 614. The elongated fin structures are narrower than the planar active regions of the source/drain active region 608 and the source/drain active region 610. The planar active regions of the source/drain active region 608 and the source/drain active region 610 may be approximately square shaped, approximately rectangular shaped, approximately circular shaped, and/or another shape. A ratio between a length to a width of each of the elongated fin structures is greater relative to a ratio between a length to a width of the planar active regions. The STI regions 612 are included between the plurality of fin active regions 606, whereas the planar active region is a singular structure and the STI regions 612 are around only the perimeter of the planar active regions.

FIG. 6C illustrates a cross-section view along line G-G in FIG. 6A. The cross-section view of FIG. 6C is in a plane along the channel active region 626 between the source/drain active region 608 and the source/drain active region 610. As shown in FIG. 6C, the high-voltage transistor in the device region 602 of the semiconductor device 600 may further include a well region 628 under the source/drain region 622. The well region 628 may include a p-well region, an n-well region, or a combination thereof. The well region 628 may facilitate the flow of current from the source/drain region 622 to the source/drain region 624 through the channel active region 626. The substrate 604 may also include a another well region, which may be doped with an opposite type of dopants relative to the well region 628.

High-voltage STI regions 630 may be included in the substrate 604. The high-voltage STI regions 630 may configured to provide additional electrical isolation between adjacent high-voltage transistors in the device region 602. A high-voltage STI region 630 may be included on a side of the source/drain region 622 opposing another side of the source/drain region 622 that is facing the gate structure 614. Another high-voltage STI region 630 may be included on a side of the source/drain region 624 opposing another side of the source/drain region 624 that is facing the gate structure 614.

As indicated above, FIGS. 6A-6C are provided as examples. Other examples may differ from what is described with regard to FIG. 6A-6C.

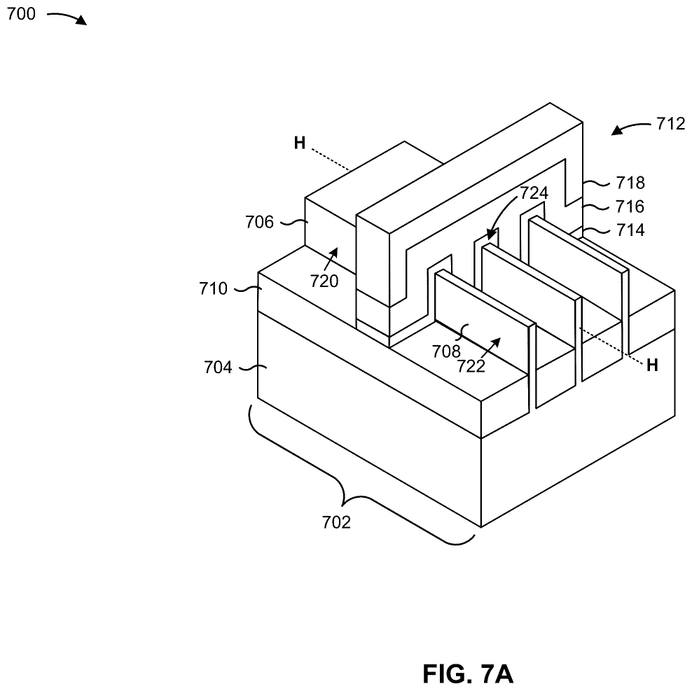

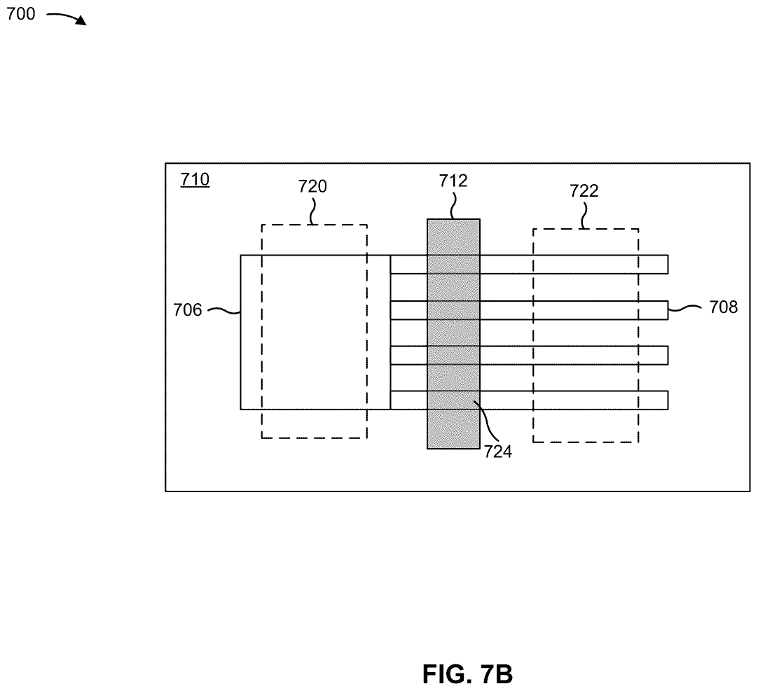

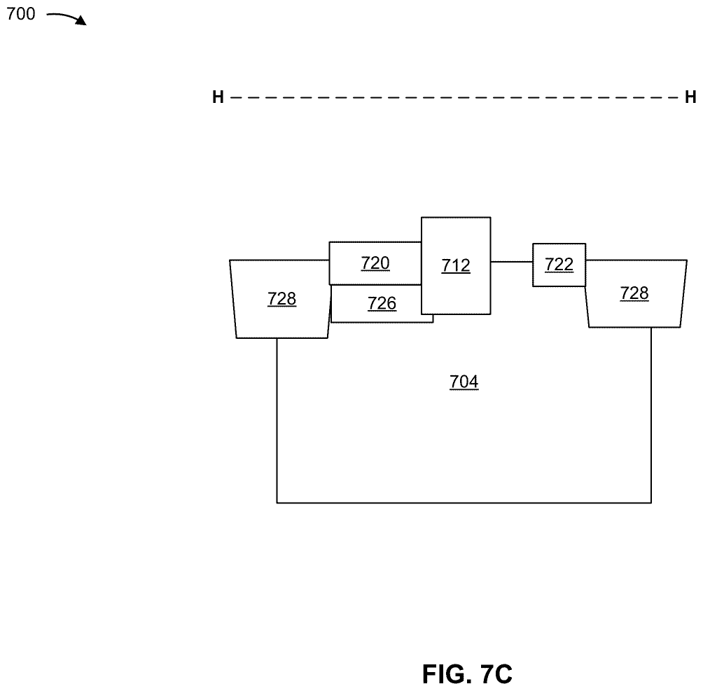

FIGS. 7A-7C are diagrams of an example semiconductor device 700 described herein. In particular, FIGS. 7A-7C illustrate an example device region 702 of the semiconductor device 700 in which one or more high-voltage transistors or other devices are included. The high-voltage transistors may include high-voltage fin-based transistors, such as high-voltage finFETs, high-voltage nanostructure transistors, and/or other types of high-voltage transistors. In some implementations, the device region 702 includes a PMOS region, an NMOS region, a CMOS region, and/or another type of device region.

As shown in FIG. 7A, an example high-voltage transistor in the device region 702 of the semiconductor device 700 may include a substrate 704, a source/drain active region 706, a source/drain active region 708, STI regions 710, a gate structure 712 (which may include a gate dielectric layer 714, a gate electrode layer 716, a capping layer 718, and/or another layer), a source/drain region 720, a source/drain region 722, and a channel active region 724. In some implementations, the source/drain active region 706 may include a source active region and the source/drain active region 708 may include a drain active region. These structures may be similar to the corresponding structures described above in connection with FIG. 2A. However, the source/drain active region 706 includes a planar active region (e.g., a planar source active region) instead of a plurality of fin active regions (e.g., fin source active regions), and the source/drain active region 708 includes a plurality of fin active regions (e.g., fin drain active regions) as opposed to a planar active region (e.g., a planar drain active region). Moreover, a gate STI region is omitted from the semiconductor device 700. Instead, the plurality of fin active regions of the source/drain active region 708 are directly connected with (and/or physically contacting) the channel active region 724.

FIG. 7B illustrates a top-down view of the device region 702 of the semiconductor device 700. The high-voltage transistor in the device region 702 of the semiconductor device 700 may include the source/drain region 720 that includes a source/drain active region 706. The high-voltage transistor in the device region 702 of the semiconductor device 700 may include a source/drain region 722 that includes a source/drain active region 708. The high-voltage transistor in the device region 702 of the semiconductor device 700 may include a channel active region 724 between the source/drain active region 706 and the source/drain active region 708. The high-voltage transistor in the device region 702 of the semiconductor device 700 may include a gate structure 712 over the channel active region 724. The gate structure 712 may be between the source/drain active region 706 and the source/drain active region 708, and may wrap around the channel active region 724 on at least three sides of the channel active region 724. The source/drain active region 706 and the source/drain active region 708 may be at least partially surrounded by one or more STI regions 710.

As further shown in FIG. 7B, the source/drain active region 706 may include a planar active region that extends above the substrate 704. The source/drain active region 708 may include a plurality of fin active regions that extend above the substrate 704. The channel active region 724 may include a plurality of the fin active regions under the gate structure 712.

First portions of the plurality of fin active regions of the channel active region 724 may be located under the gate structure 712 such that the gate structure 712 wraps around the first portions of the plurality of fin active regions on at least three sides of the first portions of the plurality of fin active regions of the channel active region 724. Second portions of the plurality of fin active regions of the channel active region 724 may extend outward from the gate structure 712 (and toward the source/drain active region 706) such that the second portions of the plurality of fin active regions are not under the gate structure 712. Third portions of the plurality of fin active regions of the channel active region 724 may extend outward from the gate structure 712 (and toward the source/drain active region 708) such that the third portions of the plurality of fin active regions are not under the gate structure 712. The planar active region of the source/drain active region 706 and the second portions of the plurality of fin active regions of the channel active region 724 may be directly connected and/or in direct physical contact. The plurality of fin active regions of the source/drain active region 708 and the third portions of the plurality of fin active regions of the channel active region 724 may be directly connected and/or in direct physical contact.

The plurality of fin active regions of the source/drain active region 708 and the channel active region 724 may include elongated fin structures that extend in a direction that is approximately perpendicular with the gate structure 712. The elongated fin structures are longer and narrower than the planar active region of the source/drain active region 706. The planar active region of the source/drain active region 706 may be approximately square shaped, approximately rectangular shaped, approximately circular shaped, and/or another shape. A ratio between a length to a width of each of the elongated fin structures is greater relative to a ratio between a length to a width of the planar active region. The STI regions 710 are included between the plurality of fin active regions of the drain active region 708 and between the plurality of fin active regions of the channel active region 724. The planar active region of the source active region 706 is a singular structure, and the STI regions 710 are around only the perimeter of the planar active region.

FIG. 7C illustrates a cross-section view along line H-H in FIG. 7A. The cross-section view of FIG. 7C is in a plane along the channel active region 724 between the source/drain active region 706 and the source/drain active region 708. As shown in FIG. 7C, the high-voltage transistor in the device region 702 of the semiconductor device 700 may further include a well region 726 under the source/drain region 720. The well region 726 may include a p-well region, an n-well region, or a combination thereof. The well region 726 may facilitate the flow of current from the source/drain region 720 to the source/drain region 722 through the channel active region 724. The substrate 704 may also include a another well region, which may be doped with an opposite type of dopants relative to the well region 726.

High-voltage STI regions 728 may be included in the substrate 704. The high-voltage STI regions 728 may configured to provide additional electrical isolation between adjacent high-voltage transistors in the device region 702. A high-voltage STI region 728 may be included on a side of the source/drain region 720 opposing another side of the source/drain region 720 that is facing the gate structure 712. Another high-voltage STI region 728 may be included on a side of the source/drain region 722 opposing another side of the source/drain region 722 that is facing the gate structure 712.

As indicated above, FIGS. 7A-7C are provided as examples. Other examples may differ from what is described with regard to FIG. 7A-7C.

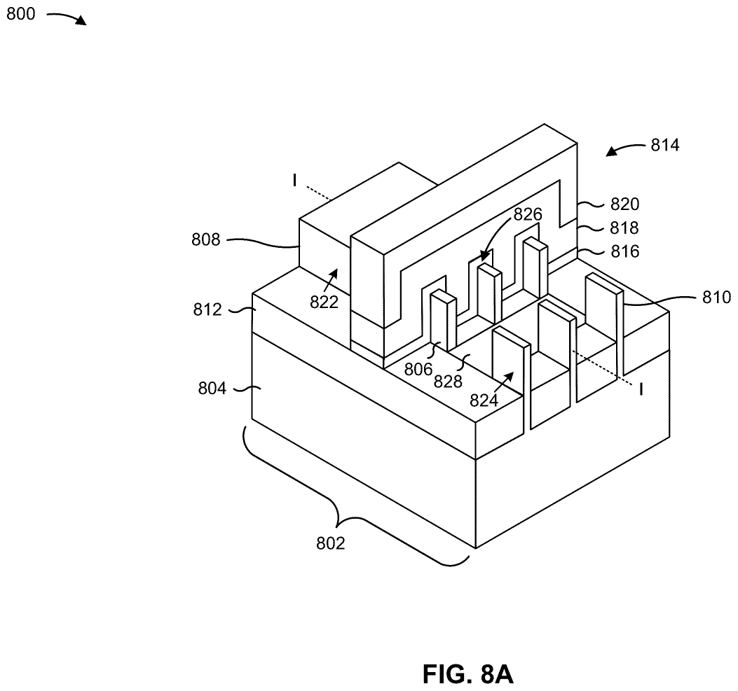

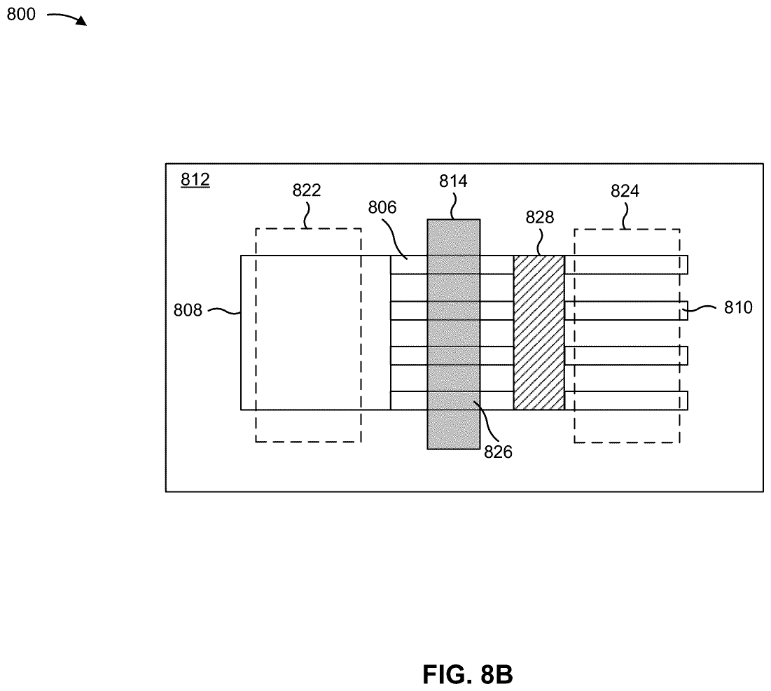

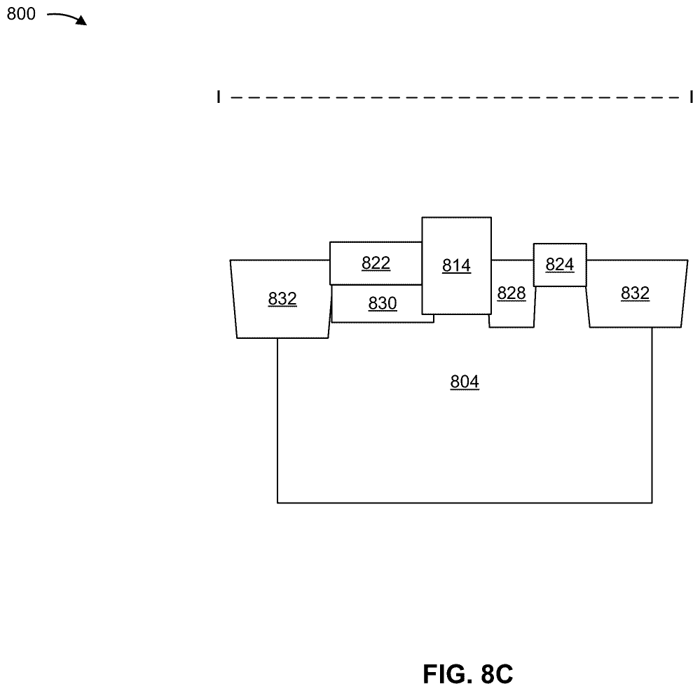

FIGS. 8A-8C are diagrams of an example semiconductor device 800 described herein. In particular, FIGS. 8A-8C illustrate an example device region 802 of the semiconductor device 800 in which one or more high-voltage transistors or other devices are included. The high-voltage transistors may include high-voltage fin-based transistors, such as high-voltage finFETs, high-voltage nanostructure transistors, and/or other types of high-voltage transistors. In some implementations, the device region 802 includes a PMOS region, an NMOS region, a CMOS region, and/or another type of device region.

As shown in FIG. 8A, an example high-voltage transistor in the device region 802 of the semiconductor device 800 may include a substrate 804, a plurality of fin active regions 806, a source/drain active region 808, a source/drain active region 810, STI regions 812, a gate structure 814 (which may include a gate dielectric layer 816, a gate electrode layer 818, a capping layer 820, and/or another layer), a source/drain region 822, a source/drain region 824, and a channel active region 826. In some implementations, the source/drain active region 808 may include a source active region and the source/drain active region 810 may include a drain active region. These structures may be similar to the corresponding structures described above in connection with FIG. 7A. However, the plurality of fin active regions (e.g., fin drain active regions) of the source/drain active region 810 and the plurality of fin active regions 806 (e.g., fin channel active regions) of the channel active region 826 are separated by a gate STI region 828 between the drain active region 810 and the channel active region 826.

FIG. 8B illustrates a top-down view of the device region 802 of the semiconductor device 800. The high-voltage transistor in the device region 802 of the semiconductor device 800 may include the source/drain region 822 that includes a source/drain active region 808. The high-voltage transistor in the device region 802 of the semiconductor device 800 may include a source/drain region 824 that includes a source/drain active region 810. The high-voltage transistor in the device region 802 of the semiconductor device 800 may include a channel active region 826 between the source/drain active region 808 and the source/drain active region 810. The high-voltage transistor in the device region 802 of the semiconductor device 800 may include a gate structure 814 over the channel active region 826. The gate structure 814 may be between the source/drain active region 808 and the source/drain active region 810. The gate structure 814 may wrap around the channel active region 826 on at least three sides of the channel active region 826. The high-voltage transistor in the device region 802 of the semiconductor device 800 may include a gate STI region 828 between the source/drain active region 810 and the channel active region 826. The gate STI region 828 may extend into the substrate 804. The source/drain active region 808 and the source/drain active region 810 may be at least partially surrounded by one or more STI regions 812.

As further shown in FIG. 8B, the source/drain active region 808 may include a planar active region that extends above the substrate 804. The source/drain active region 810 may include a plurality of fin active regions that extend above the substrate 804. The channel active region 826 may include the plurality of the fin active regions 806 under the gate structure 814. The plurality of fin active regions of the drain active region 810 and the plurality of fin active regions 806 of the channel active region 826 are separated by the gate STI region 828.

First portions of the plurality of fin active regions 806 of the channel active region 826 may be located under the gate structure 814 such that the gate structure 814 wraps around the first portions of the plurality of fin active regions 806 on at least three sides of the first portions of the plurality of fin active regions 806 of the channel active region 826. Second portions of the plurality of fin active regions 806 of the channel active region 826 may extend outward from the gate structure 814 (and toward the source/drain active region 808) such that the second portions of the plurality of fin active regions 806 are not under the gate structure 814. Third portions of the plurality of fin active regions 806 of the channel active region 826 may extend outward from the gate structure 814 (and toward the gate STI region 828) such that the third portions of the plurality of fin active regions 806 are not under the gate structure 814. The planar active region of the source/drain active region 808 and the second portions of the plurality of fin active regions 806 of the channel active region 826 may be directly connected and/or in direct physical contact.

The plurality of fin active regions of the source/drain active region 810 and the channel active region 826 may include elongated fin structures that extend in a direction that is approximately perpendicular with the gate structure 814. The elongated fin structures are longer and narrower than the planar active region of the source/drain active region 808. The planar active region of the source/drain active region 808 may be approximately square shaped, approximately rectangular shaped, approximately circular shaped, and/or another shape. A ratio between a length to a width of each of the elongated fin structures is greater relative to a ratio between a length to a width of the planar active region. The STI regions 812 are included between the plurality of fin active regions of the source/drain active region 810 and between the plurality of fin active regions 806 of the channel active region 826. The planar active region of the source/drain active region 808 is a singular structure, and the STI regions 812 are around only the perimeter of the planar active region.

FIG. 8C illustrates a cross-section view along line I-I in FIG. 8A. The cross-section view of FIG. 8C is in a plane along the channel active region 826 between the source active region 808 and the drain active region 810. As shown in FIG. 8C, the high-voltage transistor in the device region 802 of the semiconductor device 800 may further include a well region 830 under the source/drain region 822. The well region 830 may include a p-well region, an n-well region, or a combination thereof. The well region 830 may facilitate the flow of current from the source/drain region 822 to the source/drain region 824 through the channel active region 826. The substrate 804 may also include a another well region, which may be doped with an opposite type of dopants relative to the well region 830.

High-voltage STI regions 832 may be included in the substrate 804. The high-voltage STI regions 832 may configured to provide additional electrical isolation between adjacent high-voltage transistors in the device region 802. A high-voltage STI region 832 may be included on a side of the source/drain region 822 opposing another side of the source/drain region 822 that is facing the gate structure 814. Another high-voltage STI region 832 may be included on a side of the source/drain region 824 opposing another side of the source/drain region 824 that is facing the gate structure 814.

As indicated above, FIGS. 8A-8C are provided as examples. Other examples may differ from what is described with regard to FIG. 8A-8C.

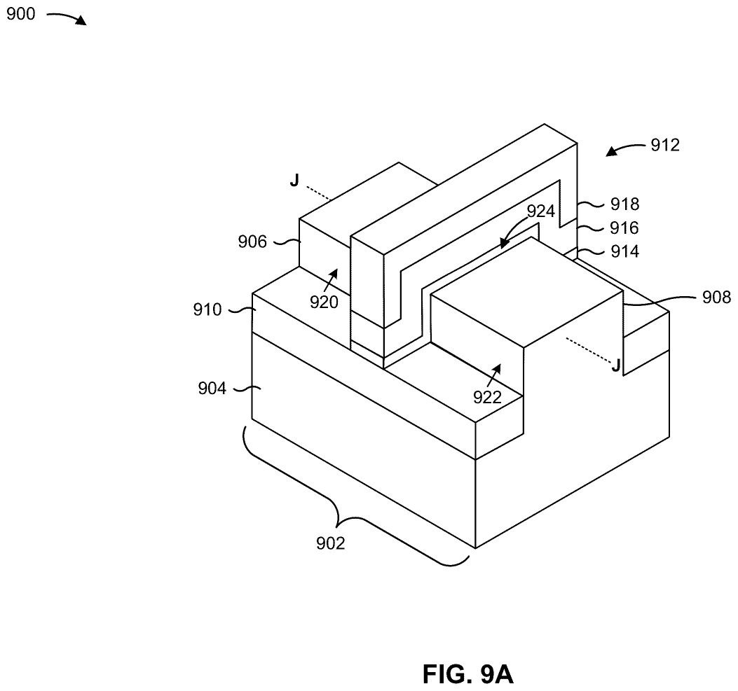

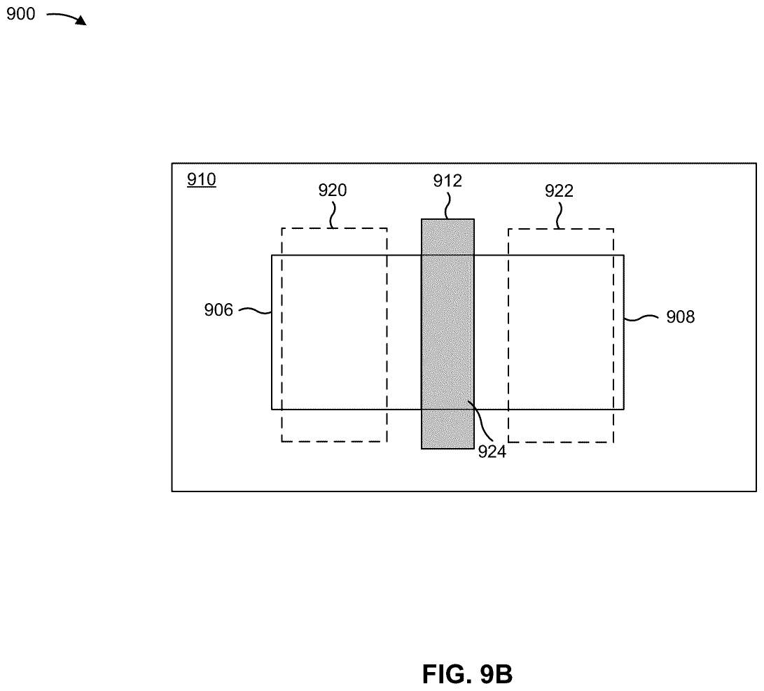

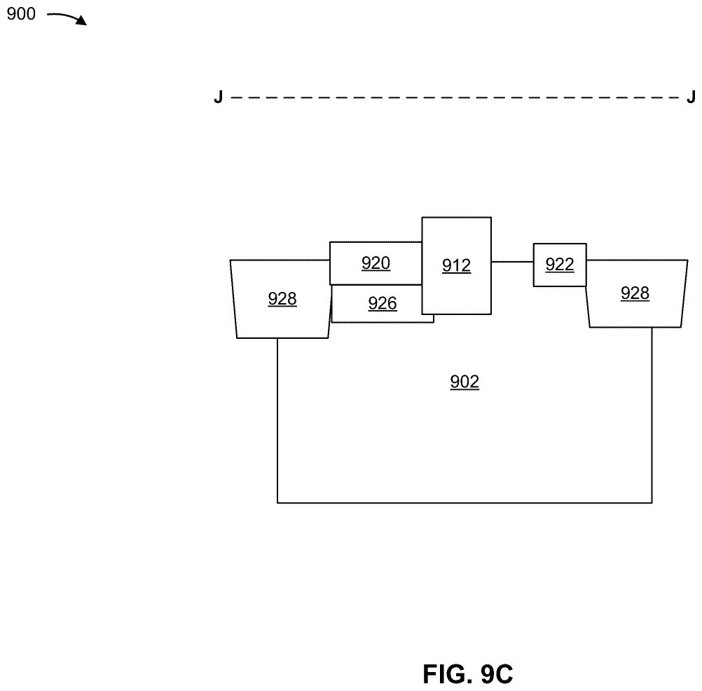

FIGS. 9A-9C are diagrams of an example semiconductor device 900 described herein. In particular, FIGS. 9A-9C illustrate an example device region 902 of the semiconductor device 600 in which one or more high-voltage transistors or other devices are included. The high-voltage transistors may include high-voltage fin-based transistors, such as high-voltage finFETs, high-voltage nanostructure transistors, and/or other types of high-voltage transistors. In some implementations, the device region 902 includes a PMOS region, an NMOS region, a CMOS region, and/or another type of device region.

FIG. 9A illustrates an example high-voltage transistor in the device region 902 of the semiconductor device 900. As shown in FIG. 9A, the structures of the high-voltage transistor in the device region 902 of the semiconductor device 900 may be similar to the corresponding structures described above in connection with FIG. 6A. However, the channel active region of the high-voltage transistor in the device region 902 of the semiconductor device 900 includes a planar active region instead of a plurality fin active regions.

As shown in FIG. 9A, the high-voltage transistor in the device region 902 of the semiconductor device 900 may include a substrate 904, a source/drain active region 906, a source/drain active region 908, STI regions 910, a gate structure 912 (which may include a gate dielectric layer 14, a gate electrode layer 916, a capping layer 918, and/or another layer), a source/drain region 920, a source/drain region 922, and a channel active region 924 under the gate structure 912. The gate structure 912 may wrap around the channel active region 924 on at least three sides of the channel active region 924. In some implementations, the source/drain active region 906 is a source active region and the source/drain active region 908 is a drain active region.

FIG. 9B illustrates a top-down view of the device region 902 of the semiconductor device 900. The high-voltage transistor in the device region 902 of the semiconductor device 900 may include the source/drain region 920 that includes the source/drain active region 906. The high-voltage transistor in the device region 902 of the semiconductor device 900 may include the source/drain region 922 that includes the source/drain active region 908. The high-voltage transistor in the device region 902 of the semiconductor device 900 may include the channel active region 924 between the source/drain active region 906 and the source/drain active region 908. The high-voltage transistor in the device region 902 of the semiconductor device 900 may include the gate structure 912 over the channel active region 924. The gate structure 912 may be between the source/drain active region 906 and the source/drain active region 908, and may wrap around the channel active region 924 on at least three sides of the channel active region 924. The source/drain active region 906 and the source/drain active region 908 may be at least partially surrounded by one or more STI regions 910.

As further shown in FIG. 9B, the source/drain active region 906 may include planar active region that extends above the substrate 904. The source/drain active region 908 may include a planar active region that extends above the substrate 904. The channel active region 924 may include a planar active region that extends above the substrate 904. The gate structure 912 may wrap around the planar active region of the channel active region 924 on at least three sides of the planar active region of the channel active region 924. In some implementations, first portions of the planar active region of the channel active region 924 extends outward from the first side of the gate structure 912 and are not under the gate structure 912.

In some implementations, second portions of the planar active region of the channel active region 924 extends outward from the second side of the gate structure 914 opposing the first side. In some implementations, the first portions of the planar active region of the channel active region 924 are directly connected with the planar active region of the source/drain active region 906. In some implementations, the second portions of the planar active region of the channel active region 924 are directly connected with the planar active region of the source/drain region 908.

The planar active region of the source/drain active region 906 and the planar active region of the channel active region 924 may be directly connected and/or in direct physical contact. The planar active region of the source/drain active region 908 and the planar active region of the channel active region 924 may be directly connected and/or in direct physical contact.

FIG. 9C illustrates a cross-section view along line J-J in FIG. 9A. The cross-section view of FIG. 9C is in a plane along the channel active region 924 between the source/drain active region 906 and the source/drain active region 908. As shown in FIG. 9C, the high-voltage transistor in the device region 902 of the semiconductor device 900 may further include a well region 926 under the source/drain region 920. The well region 926 may include a p-well region, an n-well region, or a combination thereof. The well region 926 may facilitate the flow of current from the source/drain region 920 to the source/drain region 922 through the channel active region 924. The substrate 904 may also include a another well region, which may be doped with an opposite type of dopants relative to the well region 926.

High-voltage STI regions 928 may be included in the substrate 904. The high-voltage STI regions 928 may configured to provide additional electrical isolation between adjacent high-voltage transistors in the device region 902. A high-voltage STI region 928 may be included on a side of the source/drain region 920 opposing another side of the source/drain region 920 that is facing the gate structure 912. Another high-voltage STI region 928 may be included on a side of the source/drain region 922 opposing another side of the source/drain region 922 that is facing the gate structure 912.

As indicated above, FIGS. 9A-9C are provided as examples. Other examples may differ from what is described with regard to FIG. 9A-9C.

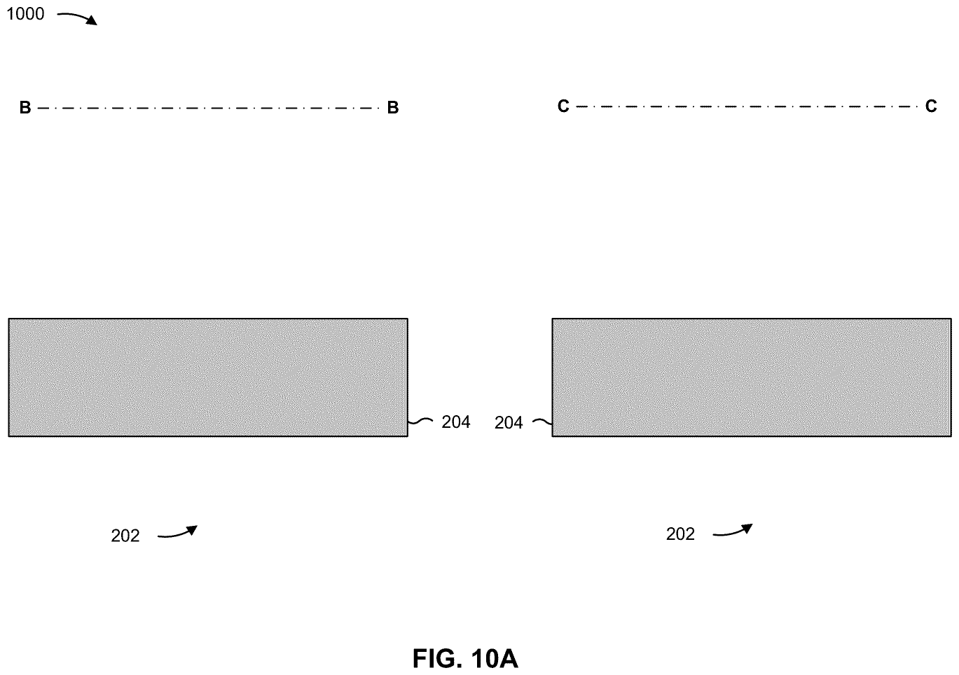

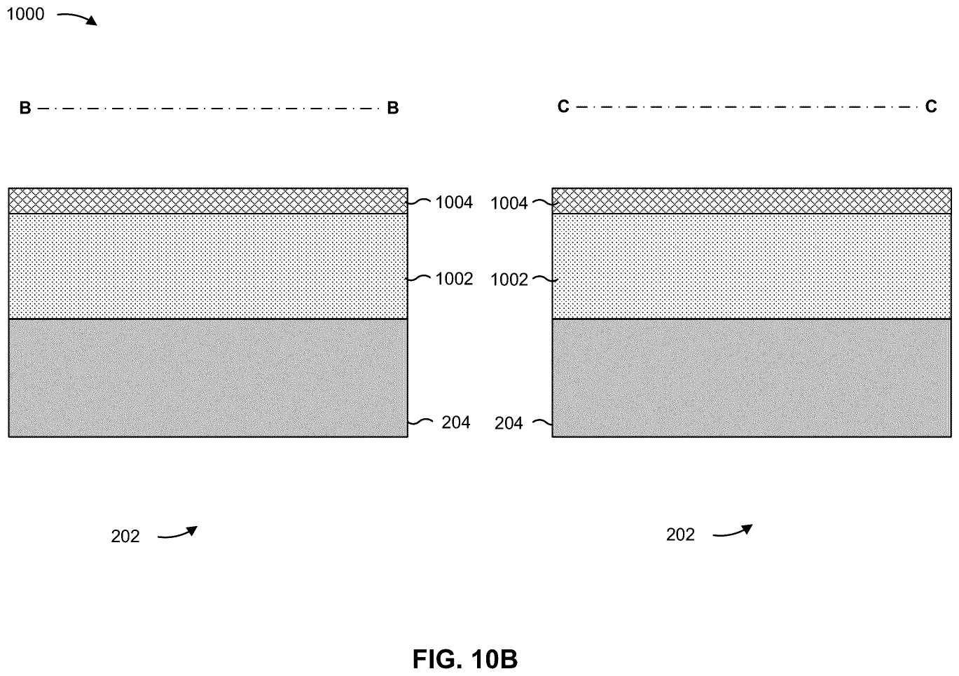

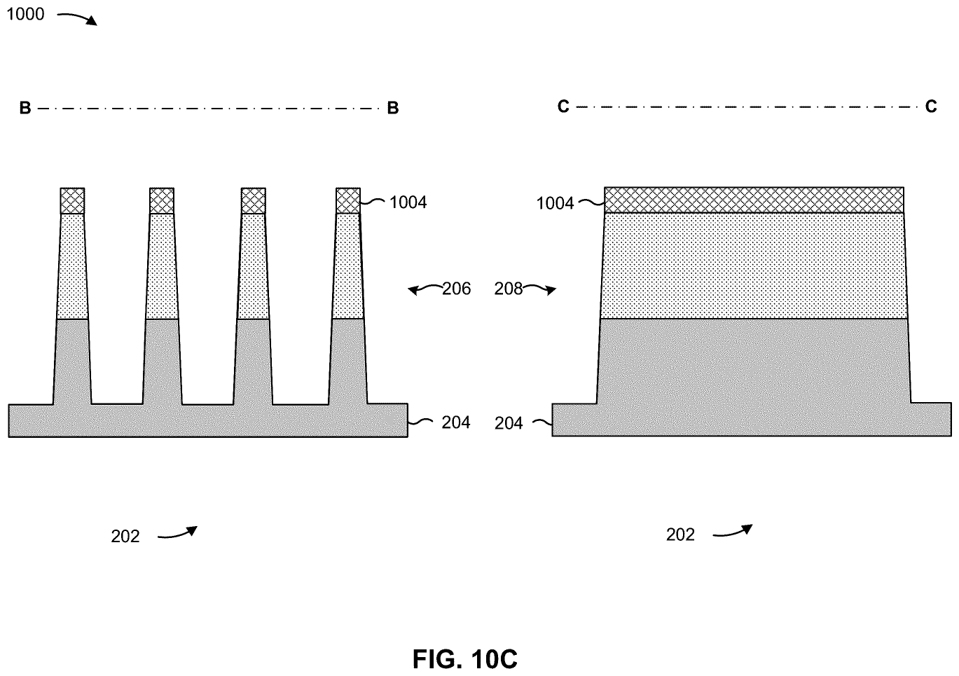

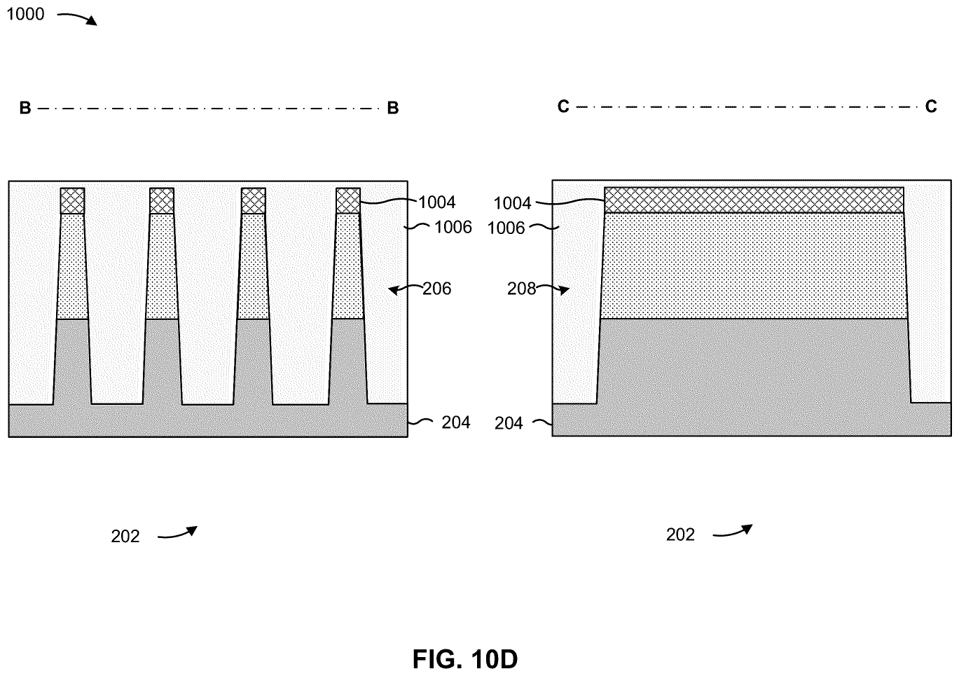

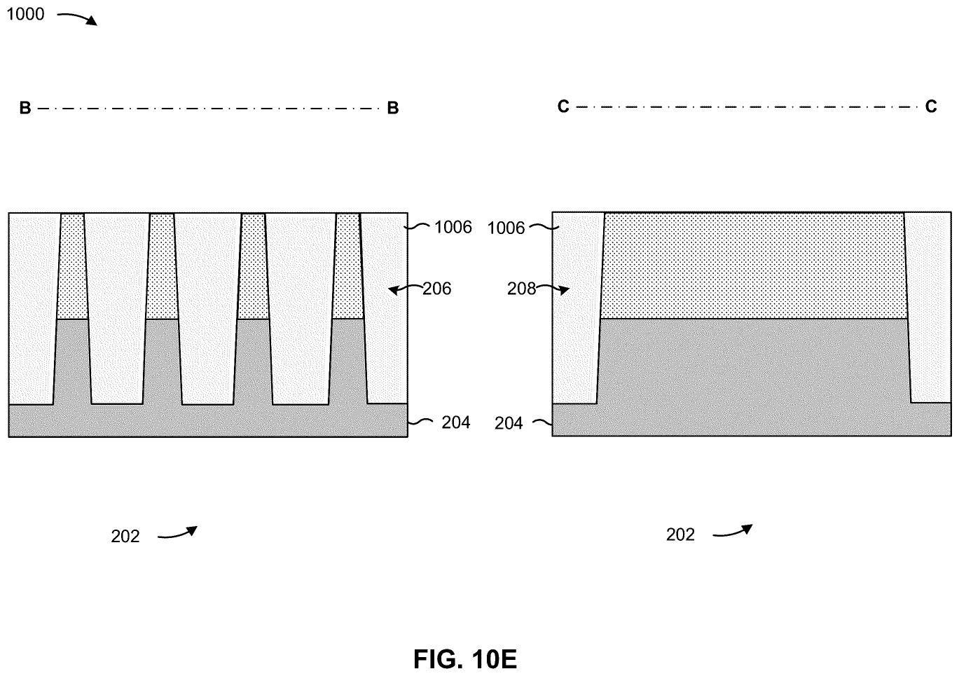

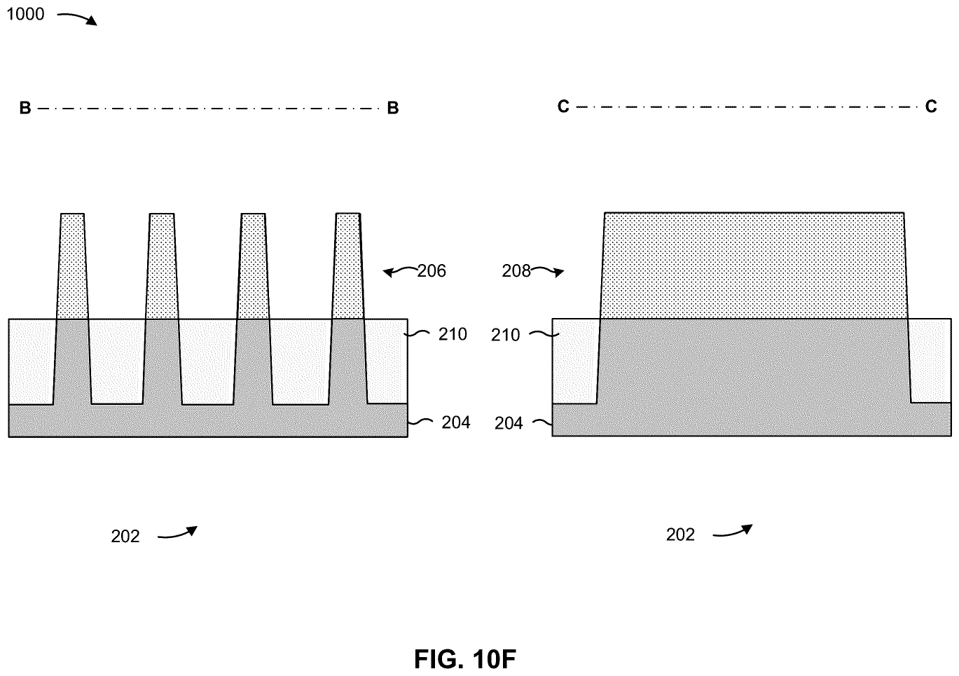

FIGS. 10A-10F are diagrams of an example implementation 1000 described herein. The example implementation 1000 includes an example of forming active regions for a high-voltage transistor described herein. The example implementation 1000 is described in connection with the device region 202 of the semiconductor device 200. However, the techniques and/or operations are described in connection with FIGS. 10A-10F in the device region 202 of the semiconductor device 200. FIGS. 10A-10F are illustrated from the perspective of the cross-sectional plane B-B in FIG. 2B and the cross-sectional plane C-C in FIG. 2B for the device region 202 of the semiconductor device 200. Turning to FIG. 10A, the example implementation 1000 includes semiconductor processing operations relating to the substrate 204 in and/or on which a high-voltage transistor is formed in the device region 202.

As shown in FIG. 10B, one or more layers may be formed over and/or on the substrate 204. The one or more layers may include an epitaxial layer 1002 and one or more hard mask layers 1004. In some implementations, the deposition tool 102 may deposit the epitaxial layer 1002 by epitaxial growth. The epitaxial layer 1002 may include a silicon (Si) epitaxial layer and/or another type of epitaxial layer. The one or more hard mask layers 1004 may include an oxide/nitride/oxide layer stack. The oxide/nitride/oxide layer stack may include a silicon oxide (SiOₓ), a silicon nitride (SiₓN_{y}), and a silicon oxide (SiOₓ). However, other layer stacks may be used for the one or more hard mask layers 1004. In some implementations, the deposition tool 102 may deposit the one or more hard mask layers 1004 using a CVD technique, a PVD technique, an ALD technique, a deposition technique described above in connection with FIG. 1, and/or another deposition technique. In these implementations, the planarization tool 110 performs a planarization (or polishing) operation to planarize the epitaxial layer 1002 and/or the one or more hard mask layers 1004.

As shown in FIG. 10C, fin active regions are formed in the source/drain active region 206, and a planar active region is formed in the drain active region 208. In some implementations, planar active regions are formed in a drain active region in a channel active region, and/or in a planar extension region, as described herein. In some implementations, a pattern in a photoresist layer is used to form a pattern in the one or more hard mask layers 1004. In these implementations, the deposition tool 102 forms the photoresist layer on the one or more hard mask layers 1004. The exposure tool 104 exposes the photoresist layer to a radiation source to pattern the photoresist layer. The developer tool 106 develops and removes portions of the photoresist layer to expose the pattern. The etch tool 108 etches into the one or more hard mask layers 1004 to form the pattern. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). The etch tool 108 may then etch into the epitaxial layer 1002 and into the substrate 204 to form the fin active regions in the source/drain active region 206, and to form the planar active region in the drain active region 208. In some implementations, a double patterning technique, a self-aligned double patterning (SADP) technique, a quadruple-aligned double patterning (QADP), and/or another type of multiple patterning technique may be used to etch the substrate 204.

As shown in FIG. 10D, a dielectric layer 1006 is formed over and in between the fin active regions in the source/drain active region 206, and over the planar active region in the drain active region 208. The deposition tool 102 deposits the dielectric layer 1006 using a CVD technique, a PVD technique, an ALD technique, a deposition technique described above in connection with FIG. 1, and/or another deposition technique. As shown in FIG. 10D, the dielectric layer 1006 may be formed to a height that is greater than the height of the fin active regions, and that is greater than the height of the planar active region.

As shown in FIG. 10E, the planarization tool 110 performs a planarization (or polishing) operation to planarize the dielectric layer 1006 such that the top surface of the dielectric layer 1006 is substantially flat and smooth, and such that the top surface of the dielectric layer 1006, the top surface of the fin active regions, and the tup surface of the planar active region are approximately the same height. The planarization operation may also remove the remaining portions of the one or more hard mask layers 1004.

As shown in FIG. 10F, the dielectric layer 1006 is etched in an etch back operation to expose portions of the fin active regions in the source/drain active region 206, and a portion of the planar active region in the drain active region 208. The etch tool 108 etches a portion of the dielectric layer 1006 using a plasma etch technique, a wet chemical etch technique, and/or another type of etch technique. The remaining portions of the dielectric layer 1006 may correspond to the STI regions 210. In some implementations, the dielectric layer 1006 is etched such that the height of the top surfaces of the STI region 210 and a height of a bottom surface of the epitaxial layer 1002 are approximately a same height.

As indicated above, FIGS. 10A-10F are provided as an example. Other examples may differ from what is described with regard to FIGS. 10A-10F.

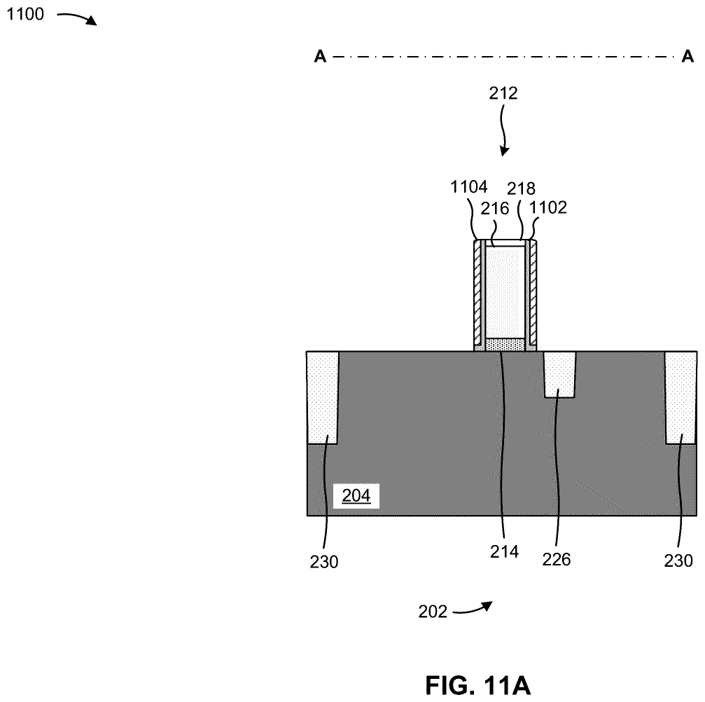

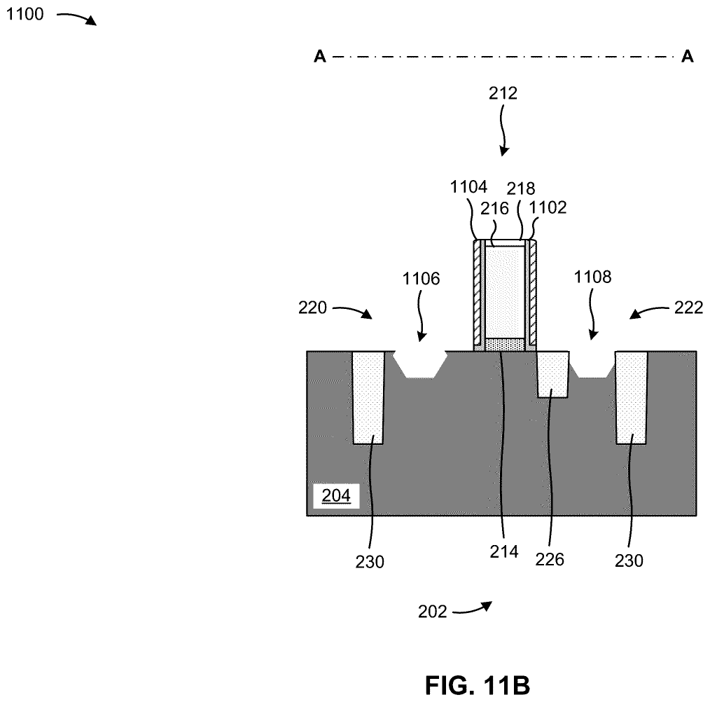

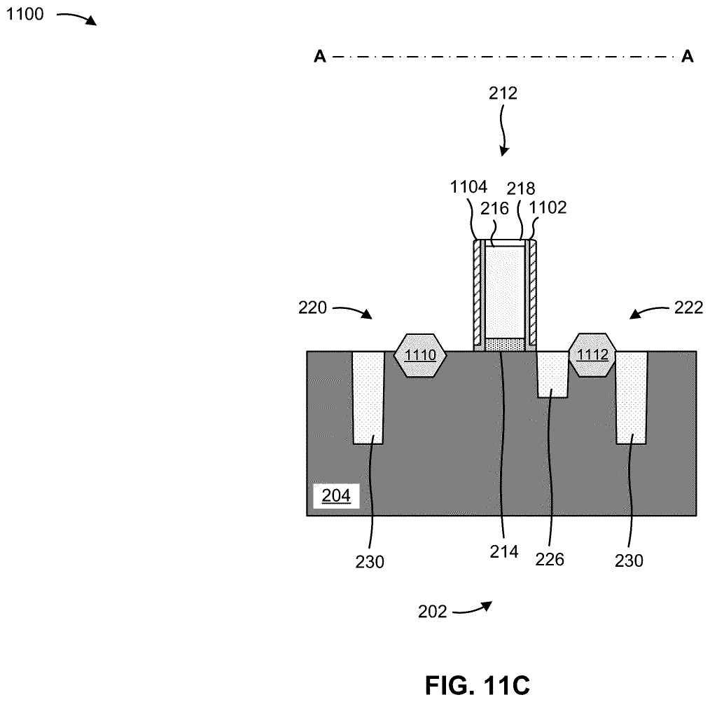

FIGS. 11A-11C are diagrams of an example implementation 1100 described herein. The example implementation 1100 includes an example of forming source/drain regions in the device region 202 of the semiconductor device 200. FIGS. 11A-11C are illustrated from the perspective of the cross-sectional plane A-A in FIG. 2A for the device region 202. In some implementations, the operations described in connection with the example implementation 1100 are performed after the fin formation process described in connection with FIGS. 10A-10F.

As shown in FIG. 11A, a gate structure 212 is formed in the device region 202. The gate structure 212 is formed and included over the channel active region 224 above the substrate 204 such that the gate structure 212 surrounds the channel active region 224 on at least three sides of the channel active region 224. The gate structure 212 may be formed as a placeholder for the actual gate structure (e.g., replacement high-k gate structure and/or metal gate structure) that is to be formed for the high-voltage transistor in the device region 202. The gate structure 212 may be formed as part of a replacement gate process, which enables other layers and/or structures to be formed prior to formation of the replacement gate structure.

The gate structure 212 may include a gate dielectric layer 214, a gate electrode layer 216, and a capping layer 218. The gate dielectric layers 214 may include a dielectric oxide layer. As an example, the gate dielectric layer 214 may be formed (e.g., by the deposition tool 102) by chemical oxidation, thermal oxidation, ALD, CVD, and/or other suitable methods. The gate electrode layer 216 may include a poly-silicon (PO) layer or other suitable layers. For example, the gate electrode layer 216 may be formed (e.g., by the deposition tool 102) by suitable deposition processes such as LPCVD or PECVD, among other examples. The capping layer 218 may include any material suitable to protect and/or pattern the gate electrode layer 216 with particular dimensions and/or attributes. Examples include silicon nitride, silicon oxynitride, silicon carbon nitride, or a combination thereof, among other examples. The capping layer 218 may be deposited (e.g., by the deposition tool 102) by CVD, PVD, ALD, or another deposition technique.

As further shown in FIG. 11A, seal spacer layers 1102 are included on the sidewalls of the gate structure 212. The seal spacer layers 1102 may be conformally deposited (e.g., by the deposition tool 102) and may include a silicon oxycarbide (SiOC), a nitrogen free SiOC, or another suitable material. The seal spacer layers 1102 may be formed by an ALD operation in which various types of precursor gasses including silicon (Si) and carbon (C) are sequentially supplied in a plurality of alternating cycles to form the seal spacer layers 1102, among other example deposition techniques.

As further shown in FIG. 11A, bulk spacer layers 1104 may be formed on the seal spacer layers 1102. The bulk spacer layers 1104 may be formed of similar materials as the seal spacer layers 1102. However, the bulk spacer layers 1104 may formed without plasma surface treatment that is used for the seal spacer layers 1102. Moreover, the bulk spacer layers 1104 may be formed to a greater thickness relative to the thickness of the seal spacer layers 1102. In some implementations, the seal spacer layers 1102 and the bulk spacer layers 1104 are conformally deposited (e.g., by the deposition tool 102) on the sidewalls of the gate structure 212.

As further shown in FIG. 11A, a gate STI region 226 and high-voltage STI regions 230 may be formed in the substrate 204. The gate STI region 226 and high-voltage STI regions 230 may be formed by etching (by the etch tool 108) the substrate 204 to form recesses in the substrate 204, and depositing (by the deposition tool 102) dielectric material in the recesses in the substrate 204 to form the gate STI region 226 and the high-voltage STI regions 230.

As shown in FIG. 11B, recesses 1106 and 1108 may be respectively formed in the source/drain region 220 and in the source/drain region 222 in an etch operation. In some implementations, the etch tool 108 etches into the source/drain active region 206 to form the recess 1106 in the source/drain region 220, and etches into the drain active region 208 to form the recess 1108 in the source/drain region 222.

As shown in FIG. 11C, a source epitaxial structure 1110 may be formed in the recess 1106 in the source/drain region 220 of the source/drain active region 206. The deposition tool 102 forms the source epitaxial structure 1110 in an epitaxial operation. A drain epitaxial structure 1112 may be formed in the recess 1108 in the source/drain region 222 of the drain active region 208. The deposition tool 102 forms the drain epitaxial structure 1112 in an epitaxial operation.

As indicated above, FIGS. 11A-11C are provided as an example. Other examples may differ from what is described with regard to FIGS. 11A-11C.

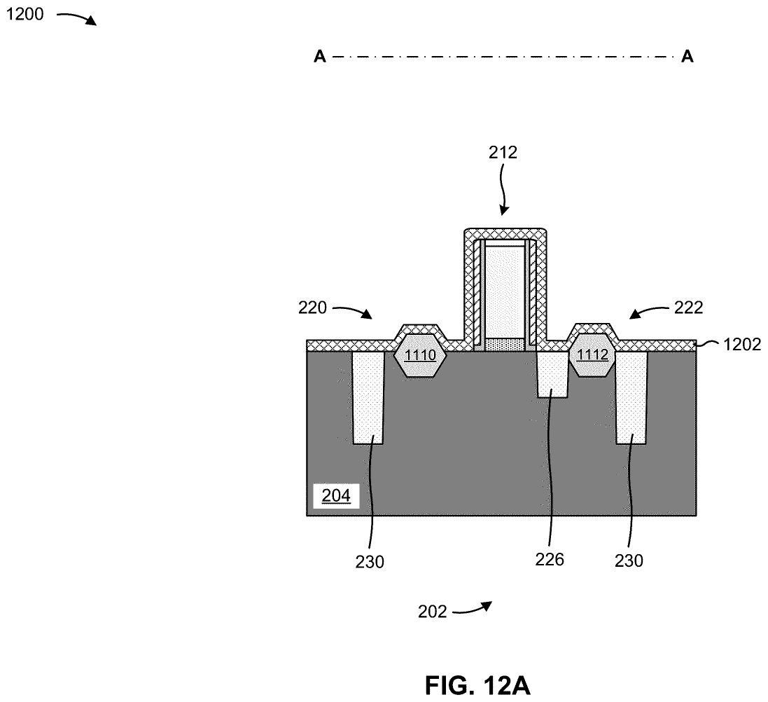

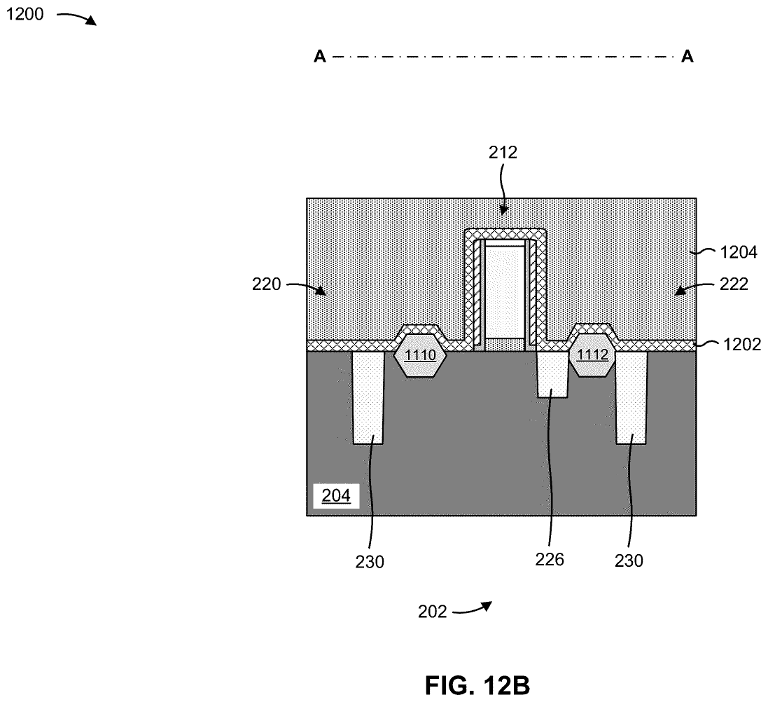

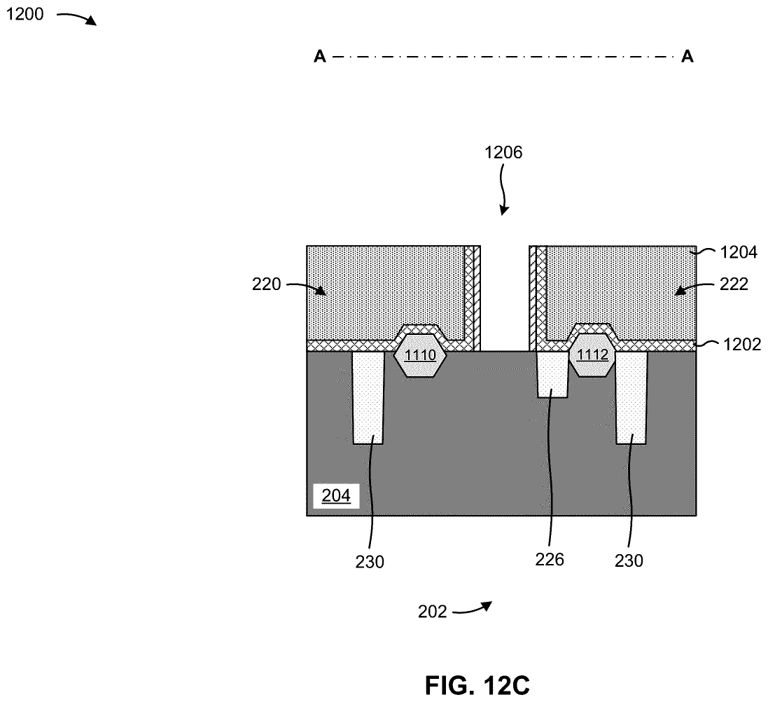

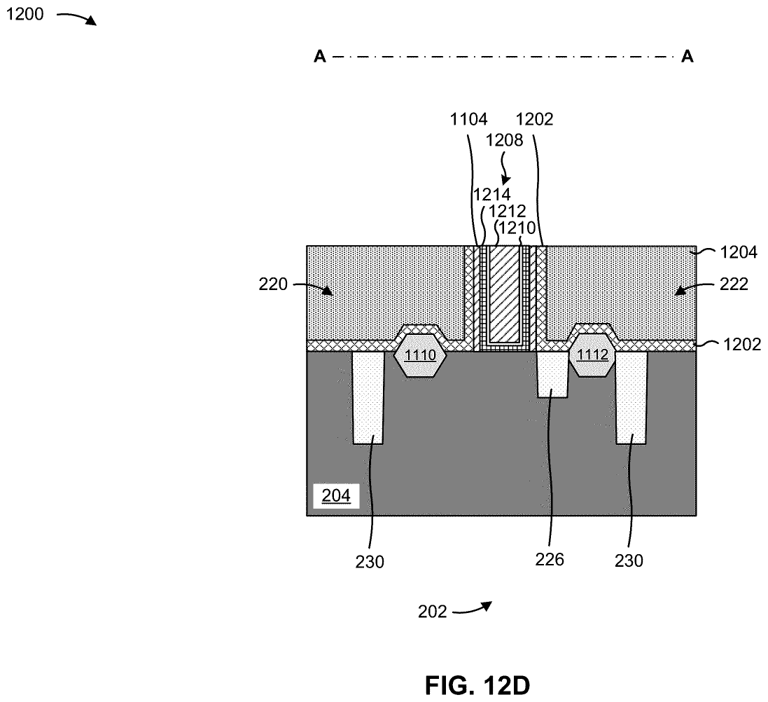

FIGS. 12A-12D are diagrams of an example implementation 1200 described herein. The example implementation 1200 includes an example dummy gate replacement process, in which the gate structure 212 is replaced with high-k gate structures and/or metal gate structures. FIGS. 12A-12D are illustrated from the perspective of the cross-sectional plane A-A in FIG. 2A for the device region 202.

As shown in FIG. 12A, a contact etch stop layer (CESL) 1202 is conformally deposited (e.g., by the deposition tool 102) over the source epitaxial structure 1110, over the drain epitaxial structure 1112, and over the gate structure 212. The CESL 1202 may provide a mechanism to stop an etch process when forming contacts or vias for the device region 202. The CESL 1202 may be formed of a dielectric material having a different etch selectivity from adjacent layers or components. The CESL 1202 may include or may be a nitrogen containing material, a silicon containing material, and/or a carbon containing material. Furthermore, the CESL 1202 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 1202 may be deposited using a deposition process, such as ALD, CVD, or another deposition technique.

As shown in FIG. 12B, an ILD layer 1204 is formed (e.g., by the deposition tool 102) over and/or on the CESL 1202. The ILD layer 1204 fills in the areas surrounding the gate structures 212 over the source epitaxial structure 1110 and over the drain epitaxial structure 1112. The ILD layer 1204 is formed to permit a replacement gate structure process to be performed in the device region 202, in which metal gate structures are formed to replace the gate structure 212. The ILD layer 1204 may be referred to as an ILD zero (ILD0) layer.

In some implementations, the ILD layer 1204 is formed to a height (or thickness) such that the ILD layer 1204 covers the gate structure 212. In these implementations, a subsequent CMP operation (e.g., performed by the planarization tool 110 is performed to planarize the ILD layer 1204 such that the top surfaces of the ILD layer 1204 are approximately at a same height as the top surfaces of the gate structure 212. The increases the uniformity of the ILD layer 1204.

As shown in FIG. 12C, the replacement gate operation is performed (e.g., by one or more of the semiconductor processing tools 102-112) to remove the gate structure 212 from the device region 202. The removal of the gate structure 212 leaves behind an opening (or recesses) 1206 between the bulk spacer layers 1104 and between the source epitaxial structure 1100 and the drain epitaxial structure 1112. The gate structure 212 may be removed in one or more etch operations includes a plasma etch technique, which may include a wet chemical etch technique, and/or another type of etch technique.

As shown in FIG. 12D, the replacement gate operation continues where deposition tool 102 and/or the plating tool 112 forms a gate structure (e.g., replacement gate structures) 1208 in the opening 1206 between the bulk spacer layers 1104 and between the source epitaxial structure 1110 and the drain epitaxial structure 1112. The gate structure 1208 may include a high-k dielectric layer 1210, a work function tuning layer 1212, a metal electrode structure 1214, and/or another layer. In some implementations, the gate structures 1208 may include other compositions of materials and/or layers.

As indicated above, FIGS. 12A-12D are provided as an example. Other examples may differ from what is described with regard to FIGS. 12A-12D.

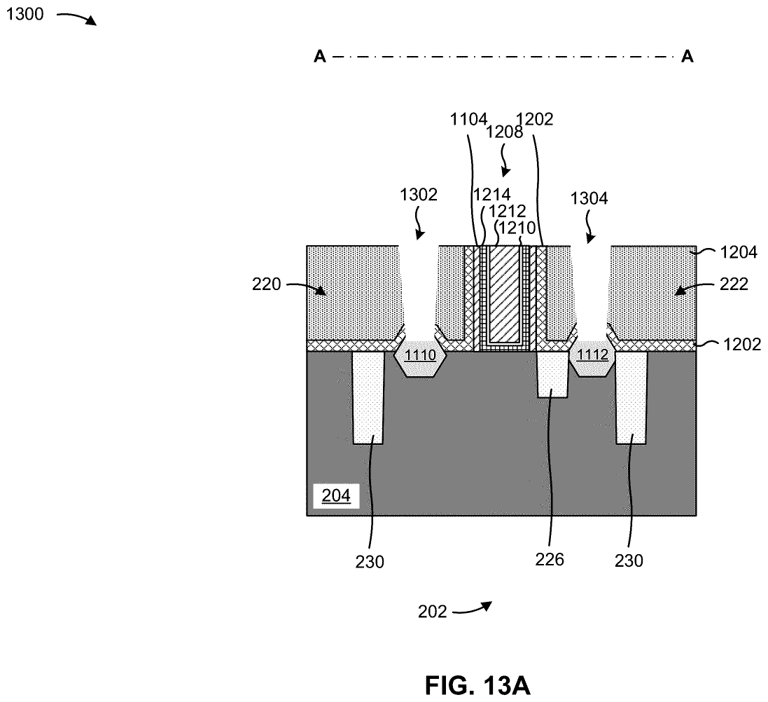

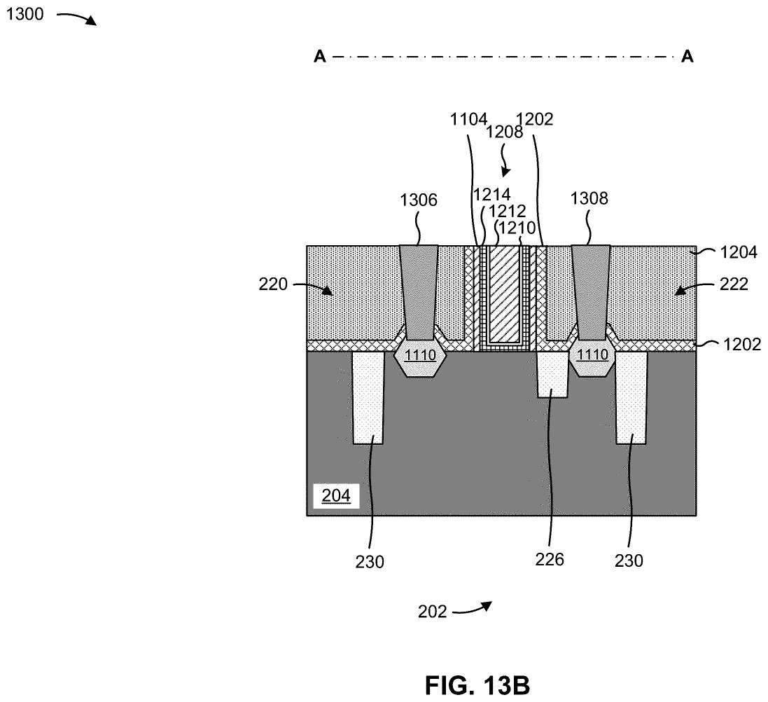

FIGS. 13A and 13B are diagrams of an example implementation 1300 described herein. The example implementation 1300 includes an example of forming conductive structures (e.g., metal gate contacts or MDs) in the device region 202 of the semiconductor device 200. FIGS. 13A and 13B are illustrated from the perspective of the cross-sectional plane A-A in FIG. 2A for the device region 202.

As shown in FIG. 13A, an opening (or recess) 1302 is formed through one or more dielectric layers and to the source epitaxial structure 1110 in the source/drain region 220 of the source/drain active region 206. In particular, the CESL 1202 and the ILD layer 1204 are etched to form the opening 1302 to the source epitaxial structure 1110. As further shown in FIG. 13A, an opening (or recess) 1304 is formed through one or more dielectric layers and to the drain epitaxial structure 1112 in the source/drain region 222 of the drain active region 208. In particular, the CESL 1202 and the ILD layer 1204 are etched to form the opening 1304 to the drain epitaxial structure 1112. In some implementations, the opening 1302 is formed in a portion of the source epitaxial structure 1110 such that opening 1302 extends into a portion of the source epitaxial structure 1110. In some implementations, the opening 1304 is formed in a portion of the drain epitaxial structure 1112 such that opening 1304 extends into a portion of the drain epitaxial structure 1112.

In some implementations, a pattern in a photoresist layer is used to form the openings 1302 and 1304. In these implementations, the deposition tool 102 forms the photoresist layer on the ILD layer 1204. The exposure tool 104 exposes the photoresist layer to a radiation source to pattern the photoresist layer. The developer tool 106 develops and removes portions of the photoresist layer to expose the pattern. The etch tool 108 etches into the ILD layer 1204 to form the openings 1302 and 1304. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the openings 1302 and 1304 based on a pattern.

As shown in FIG. 13B, a conductive structures 1306 is formed in the device region 202 over the source epitaxial structure 1110 in the opening 1302. As further shown in FIG. 13B, a conductive structures 1308 is formed in the device region 202 over the drain epitaxial structure 1112 in the opening 1304. The deposition tool 102 and/or the plating tool 112 deposits the conductive structures 1306 and 1308 by a CVD technique, a PVD technique, an ALD technique, an electroplating technique, another deposition technique described above in connection with FIG. 1, and/or a deposition technique other than as described above in connection with FIG. 1. In some implementations, one or more additional layers are formed in the openings 1302 and 1304 prior to formation of the conductive structures 1306 and 1308. As an example, a metal silicide layer (e.g., titanium nitride (TiSiₓ) or another metal silicide layer) may be formed in the openings 1302 and 1304 prior to formation of the conductive structures 1306 and 1308.

As indicated above, FIGS. 13A and 13B are provided as an example. Other examples may differ from what is described with regard to FIGS. 13A and 13B.

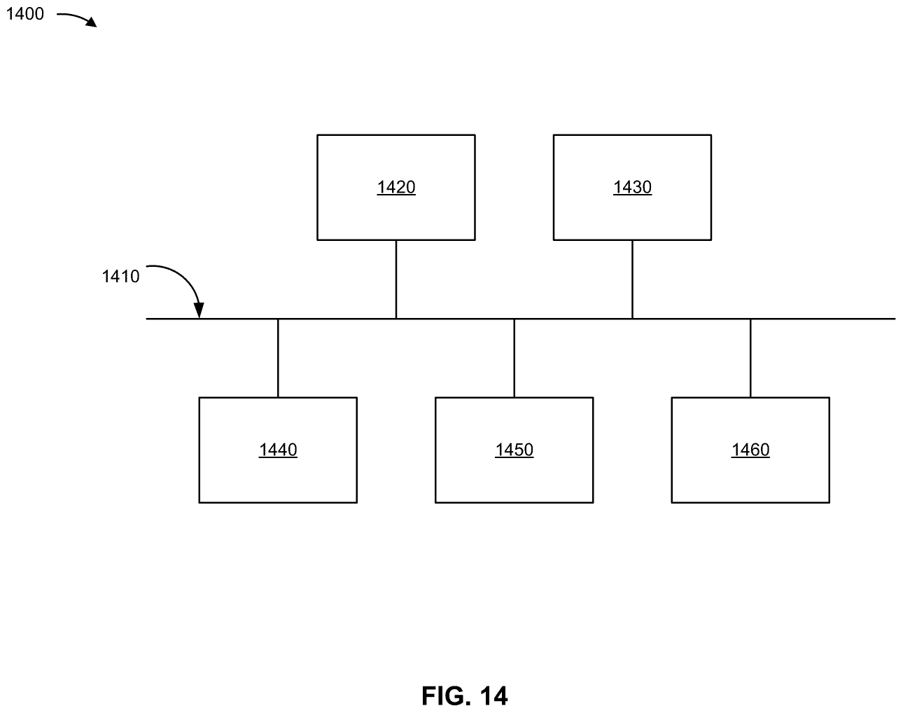

FIG. 14 is a diagram of example components of a device 1400. In some implementations, one or more of the semiconductor processing tools 102-112 and/or the wafer/die transport tool 114 may include one or more devices 1400 and/or one or more components of device 1400. As shown in FIG. 14, device 1400 may include a bus 1410, a processor 1420, a memory 1430, an input component 1440, an output component 1450, and a communication component 1460.

Bus 1410 includes one or more components that enable wired and/or wireless communication among the components of device 1400. Bus 1410 may couple together two or more components of FIG. 14, such as via operative coupling, communicative coupling, electronic coupling, and/or electric coupling. Processor 1420 includes a central processing unit, a graphics processing unit, a microprocessor, a controller, a microcontroller, a digital signal processor, a field-programmable gate array, an application-specific integrated circuit, and/or another type of processing component. Processor 1420 is implemented in hardware, firmware, or a combination of hardware and software. In some implementations, processor 1420 includes one or more processors capable of being programmed to perform one or more operations or processes described elsewhere herein.

Memory 1430 includes volatile and/or nonvolatile memory. For example, memory 1430 may include random access memory (RAM), read only memory (ROM), a hard disk drive, and/or another type of memory (e.g., a flash memory, a magnetic memory, and/or an optical memory). Memory 1430 may include internal memory (e.g., RAM, ROM, or a hard disk drive) and/or removable memory (e.g., removable via a universal serial bus connection). Memory 1430 may be a non-transitory computer-readable medium. Memory 1430 stores information, instructions, and/or software (e.g., one or more software applications) related to the operation of device 1400. In some implementations, memory 1430 includes one or more memories that are coupled to one or more processors (e.g., processor 1420), such as via bus 1410.

Input component 1440 enables device 1400 to receive input, such as user input and/or sensed input. For example, input component 1440 may include a touch screen, a keyboard, a keypad, a mouse, a button, a microphone, a switch, a sensor, a global positioning system sensor, an accelerometer, a gyroscope, and/or an actuator. Output component 1450 enables device 1400 to provide output, such as via a display, a speaker, and/or a light-emitting diode. Communication component 1460 enables device 1400 to communicate with other devices via a wired connection and/or a wireless connection. For example, communication component 1460 may include a receiver, a transmitter, a transceiver, a modem, a network interface card, and/or an antenna.

Device 1400 may perform one or more operations or processes described herein. For example, a non-transitory computer-readable medium (e.g., memory 1430) may store a set of instructions (e.g., one or more instructions or code) for execution by processor 1420. Processor 1420 may execute the set of instructions to perform one or more operations or processes described herein. In some implementations, execution of the set of instructions, by one or more processors 1420, causes the one or more processors 1420 and/or the device 1400 to perform one or more operations or processes described herein. In some implementations, hardwired circuitry is used instead of or in combination with the instructions to perform one or more operations or processes described herein. Additionally, or alternatively, processor 1420 may be configured to perform one or more operations or processes described herein. Thus, implementations described herein are not limited to any specific combination of hardware circuitry and software.

The number and arrangement of components shown in FIG. 14 are provided as an example. Device 1400 may include additional components, fewer components, different components, or differently arranged components than those shown in FIG. 14. Additionally, or alternatively, a set of components (e.g., one or more components) of device 1400 may perform one or more functions described as being performed by another set of components of device 1400.

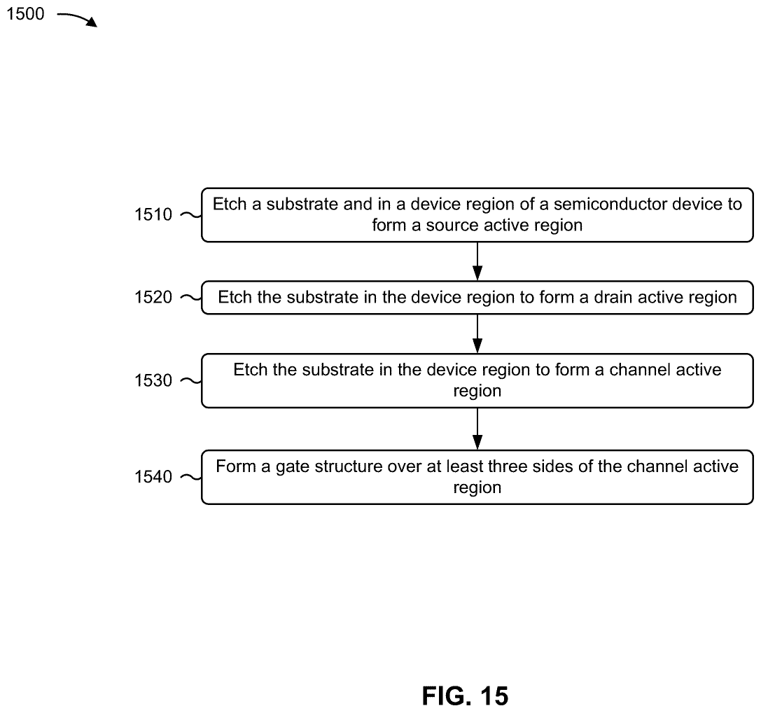

FIG. 15 is a flowchart of an example process 1500 associated with forming a semiconductor device. In some implementations, one or more process blocks of FIG. 15 are performed by one or more semiconductor processing tools (e.g., one or more of the semiconductor processing tools 102-112). Additionally, or alternatively, one or more process blocks of FIG. 15 may be performed by one or more components of device 1400, such as processor 1420, memory 1430, input component 1440, output component 1450, and/or communication component 1460.

As shown in FIG. 15, process 1500 may include etching a substrate in a device region of a semiconductor device to form a first source/drain active region (block 1510). For example, one or more of the semiconductor processing tools 102-112 may etch a substrate (e.g., one or more of the substrates 204-904) and in a device region (e.g., one or more of the device regions 202-902) of a semiconductor device (e.g., one or more of the semiconductor devices 200-900) to form a first source/drain active region (e.g., one or more of the source/drain active regions 206, 306, 406, 508, 608, 706, 808, and/or 906), as described above.

As further shown in FIG. 15, process 1500 may include etching the substrate in the device region to form a second source/drain active region (block 1520). For example, one or more of the semiconductor processing tools 102-112 may etch the substrate in the device region to form a second source/drain active region (e.g., one or more of the drain active regions 208, 308, 408, 510, 610, 708, 810, and/or 908), as described above. In some implementations, the first source/drain active region is a source active region, and the second source/drain active region is a drain active region.

As further shown in FIG. 15, process 1500 may include etching the substrate in the device region to form a channel active region (block 1530). For example, one or more of the semiconductor processing tools 102-112 may etch the substrate in the device region to form a channel active region (e.g., one or more of the channel active regions 224, 324, 424, 526, 626, 724, 826, and/or 924), as described above. In some implementations, the channel active region is between the first source/drain active region and the second source/drain active region. In some implementations, at least one of the first source/drain active region, the second source/drain active region, or the channel active region includes a planar active region.

As further shown in FIG. 15, process 1500 may include forming a gate structure over at least three sides of the channel active region (block 1540). For example, one or more of the semiconductor processing tools 102-112 may form a gate structure (e.g., one or more of the gate structure 212, 312, 412, 514, 614, 712, 814, and/or 912) over at least three sides of the channel active region, as described above.

Process 1500 may include additional implementations, such as any single implementation or any combination of implementations described below and/or in connection with one or more other processes described elsewhere herein.

In a first implementation, process 1500 includes forming a gate STI region (e.g., one or more of the gate STI regions 226, 428, 528, and/or 828) in the substrate between the channel active region and the drain active region. In a second implementation, alone or in combination with the first implementation, the source active region includes the planar active region. In a third implementation, alone or in combination with one or more of the first and second implementations, the first source/drain active region includes a first planar active region, and the second source/drain active region includes a second planar active region. In a fourth implementation, alone or in combination with one or more of the first through third implementations, the first source/drain active region includes a first planar active region, wherein the second source/drain active region includes a second planar active region, and the channel active region includes a third planar active region.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

In this way, a high-voltage transistor may include a planar active region for a source active region, a drain active region, and/or a channel active region. The planar active region(s) are included instead of a plurality of fin active regions to reduce the amount of surface area of the active regions in the high-voltage transistor that is in contact with surrounding dielectric layers of the high-voltage transistor. In other words, the planar active region(s) reduce the interface surface area between the silicon-based active regions of the high-voltage transistor and the surrounding oxide-based dielectric layers. The reduce1d interface surface area may reduce the occurrence of charge trapping in the high-voltage transistor, which may result in increased performance stability for the high-voltage transistor and/or may provide increased operational lifetime of the high-voltage transistor. For example, the reduced occurrence of charge trapping in the high-voltage transistor provided by the planar active region(s) may result in increased operation stability, increased reliability, increased time-TDDB times for the dielectric layers of the high-voltage transistor, and/or increased HCl performance, among other examples.

As described in greater detail above, some implementations described herein provide a semiconductor device. The semiconductor device includes a first source/drain region including a first source/drain active region that extends above a substrate of the semiconductor device. The semiconductor device includes a second source/drain region including a second source/drain active region that extends above the substrate, where at least one of the first source/drain active region or the second source/drain active region includes a planar active region. The semiconductor device includes a channel active region between the first source/drain active region and the second source/drain active region and extending above the substrate. The semiconductor device includes a gate structure over the channel active region and wrapping around the channel active region on at least three sides of the channel active region. The semiconductor device includes a gate STI region between the channel active region and the second source/drain active region, and extending into the substrate.

As described in greater detail above, some implementations described herein provide a semiconductor device. The semiconductor device includes a first source/drain region including a first source/drain active region that extends above a substrate of the semiconductor device. The semiconductor device includes a second source/drain region including a second source/drain active region that extends above the substrate, where at least one of the first source/drain active region or the second source/drain active region includes a planar active region. The semiconductor device includes a channel active region between the first source/drain active region and the second source/drain active region and extending above the substrate, where the second source/drain active region and the channel active region are directly connected. The semiconductor device includes a gate structure over the channel active region and wrapping around the channel active region on at least three sides of the channel active region.

As described in greater detail above, some implementations described herein provide a method. The method includes etching a substrate and in a device region of a semiconductor device to form a first source/drain active region. The method includes etching the substrate in the device region to form a second source/drain active region. The method includes etching the substrate in the device region to form a channel active region, where the channel active region is between the first source/drain active region and the second source/drain active region, and where at least one of the first source/drain active region, the second source/drain active region, or the channel active region includes a planar active region. The method includes forming a gate structure over at least three sides of the channel active region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first source/drain region comprising a first source/drain active region that extends above a substrate of the semiconductor device;
a second source/drain region comprising a second source/drain active region that extends above the substrate
wherein at least one of the first source/drain active region or the second source/drain active region comprises a planar active region;
a channel active region between the first source/drain active region and the second source/drain active region and extending above the substrate;
a gate structure over the channel active region and wrapping around the channel active region on at least three sides of the channel active region; and
a gate shallow trench isolation (STI) region between the channel active region and the second source/drain active region, and extending into the substrate.

2. The semiconductor device of claim 1, wherein the first source/drain active region comprises a plurality of fin source active regions;
wherein the second source/drain active region comprises a planar drain active region; and
wherein the channel active region comprises a plurality of fin channel active regions.

3. The semiconductor device of claim 1, wherein the first source/drain active region comprises a plurality of fin source active regions;
wherein the second source/drain active region comprises a planar drain active region; and
wherein the channel active region comprises:
a plurality of fin channel active regions; and
a planar extension region directly connected with the plurality of fin channel active regions under the gate structure.

4. The semiconductor device of claim 3, wherein the gate structure wraps around portions of the plurality of fin channel active regions on at least three sides of each of the portions of the plurality of fin channel active regions;
wherein the gate structure wraps around a portion of the planar extension region on at least three sides of the planar extension region;
wherein the plurality of fin source active regions are directly connected with the plurality of fin channel active regions; and
wherein the gate STI region is adjacent to another portion of the planar extension region that extends outward from and is not under the gate structure.

5. The semiconductor device of claim 1, wherein the first source/drain active region comprises a planar source active region;
wherein the second source/drain active region comprises a planar drain active region; and
wherein the channel active region comprises a plurality of fin active regions.

6. The semiconductor device of claim 5, wherein the plurality of fin active regions at least partially extend between a first side of the gate structure and a second side of the gate structure opposing the first side;
wherein the gate structure wraps around the plurality of fin active regions on at least three sides of each of the plurality of fin active regions; and
wherein a portion of the plurality of fin active regions extends outward from and is not under the gate structure.

7. The semiconductor device of claim 1, wherein the first source/drain active region comprises planar source active region;
wherein the second source/drain active region comprises a plurality of fin drain active regions; and
wherein the channel active region comprises a plurality of fin channel active regions.

8. The semiconductor device of claim 7, wherein the plurality of fin channel active regions extend between a first side of the gate structure and a second side of the gate structure opposing the first side;
wherein the gate structure wraps around the plurality of fin channel active regions on at least three sides of each of the plurality of fin channel active regions;
wherein first portions of the plurality of fin channel active regions extend outward from the first side of the gate structure and are not under the gate structure;
wherein second portions of the plurality of fin channel active regions extend outward from the second side of the gate structure;
wherein the first portions of the plurality of fin channel active regions are directly connected with the planar source active region; and
wherein the second portions of the plurality of fin channel active regions are adjacent to the gate STI region.

9. A semiconductor device, comprising:
a first source/drain region comprising a first source/drain active region that extends above a substrate of the semiconductor device;
a second source/drain region comprising a second source/drain active region that extends above the substrate
wherein at least one of the first source/drain active region or the second source/drain active region comprises a planar active region;
a channel active region between the first source/drain active region and the second source/drain active region and extending above the substrate,
wherein the second source/drain active region and the channel active region are directly connected; and
a gate structure over the channel active region and wrapping around the channel active region on at least three sides of the channel active region.

10. The semiconductor device of claim 9, wherein the first source/drain active region comprises a plurality of fin source active regions;
wherein the second source/drain active region comprises a planar drain active region; and
wherein the channel active region comprises:
a fin portion comprising a plurality of fin channel active regions; and
a planar portion comprising a planar channel active region directly connected with the plurality of fin channel active regions.

11. The semiconductor device of claim 9, wherein the first source/drain active region comprises a planar source active region;
wherein the second source/drain active region comprises a planar drain active region; and
wherein the channel active region comprises a plurality of fin active regions.

12. The semiconductor device of claim 11, wherein the plurality of fin active regions extend between a first side of the gate structure and a second side of the gate structure opposing the first side;
wherein the gate structure wraps around the plurality of fin active regions on at least three sides of each of the plurality of fin active regions;
wherein first portions of the plurality of fin active regions extend outward from the first side of the gate structure and are not under the gate structure;
wherein second portions of the plurality of fin active regions extend outward from the second side of the gate structure;
wherein the first portions of the plurality of fin active regions are directly connected with the planar source active region; and
wherein the second portions of the plurality of fin active regions are directly connected with the planar drain active region.

13. The semiconductor device of claim 9, wherein the first source/drain active region comprises the planar source active region;
wherein the second source/drain active region comprises a plurality of fin drain active regions; and
wherein the channel active region comprises a plurality of fin channel active regions are directly connected with the plurality of fin drain active regions.

14. The semiconductor device of claim 9, wherein the first source/drain active region comprises a planar source active region;
wherein the second source/drain active region comprises a planar drain active region; and
wherein the channel active region comprises a planar channel active region.

15. The semiconductor device of claim 14, wherein the planar channel active region extends between a first side of the gate structure and a second side of the gate structure opposing the first side;
wherein the gate structure wraps around the planar channel active region on at least three sides of the planar channel active region;
wherein a first portion of the planar channel active region extend outward from the first side of the gate structure and are not under the gate structure;
wherein a second portion of the planar channel active region extend outward from the second side of the gate structure;
wherein the first portion of the planar channel active region is directly connected with the planar source active region; and
wherein the second portion of the planar channel active region is directly connected with the planar drain active region.

16. A method, comprising:
etching a substrate and in a device region of a semiconductor device to form a first source/drain active region;
etching the substrate in the device region to form a second source/drain active region;
etching the substrate in the device region to form a channel active region,
wherein the channel active region is between the first source/drain active region and the second source/drain active region, and
wherein at least one of the first source/drain active region, the second source/drain active region, or the channel active region comprises a planar active region; and
forming a gate structure over at least three sides of the channel active region.

17. The method of claim 16, further comprising:
forming a gate shallow trench isolation (STI) region in the substrate between the channel active region and the second source/drain active region.

18. The method of claim 16, wherein the first source/drain active region comprises a planar source active region.

19. The method of claim 16, wherein the first source/source active region comprises a first planar active region; and
wherein the second source/drain active region comprises a second planar active region.

20. The method of claim 16, wherein the first source/drain active region comprises a first planar active region;
wherein the second source/drain active region comprises a second planar active region; and
wherein the channel active region comprises a third planar active region.
